(19) United States
(12) Patent Application Publication
(10) Pub. No.: US 2025/0275305 A1
(43) Pub. Date: Aug. 28, 2025

(54) LIGHT EMITTING ELEMENT AND DISPLAY DEVICE COMPRISING THE SAME

(71) Applicant: LG Display Co., Ltd., Seoul (KR)

(72) Inventors: IL-SOO KIM, Goyang-si (KR); MYUNGSOO HAN, Goyang-si (KR); HYOWON KWON, Paju-si (KR)

(73) Assignee: LG Display Co., Ltd., Seoul (KR)

(21) Appl. No.: 18/798,654

(22) Filed: Aug. 8, 2024

(30) Foreign Application Priority Data
Feb. 23, 2024 (KR) 10-2024-0026619

(51) Int. Cl. H01L 33/38; H01L 25/16; H01L 33/20

(52) U.S. Cl. CPC H10H 20/8314; H01L 25/167; H10H 20/819; H10H 20/8312

(57) ABSTRACT

Discussed is a light emitting element. The light emitting element includes a semiconductor layer, and a plurality of electrodes in contact with parts of the semiconductor layer. The semiconductor layer includes a first semiconductor layer, an emission layer on the first semiconductor layer, and a second semiconductor layer on the emission layer, the plurality of electrodes includes a plurality of first electrodes disposed so as to correspond to corners of the semiconductor layer, and a second electrode spaced apart from the plurality of first electrodes and disposed in a center portion of a surface of the semiconductor layer.

### CROSS-REFERENCE TO RELATED APPLICATIONS

This application claims priority to Korean Patent Application No. 10-2024-0026619 filed on Feb. 23, 2024, in the Korean Intellectual Property Office, the entire contents of which is hereby expressly incorporated by reference into the present application.

### BACKGROUND

### Field

The present disclosure relates to a light emitting element and a display device including the same, and more particularly, to a light emitting diode (LED) and a display device using the same.

### Description of the Related Art

As display devices are widely used nowadays for various applications, including as a monitor of a computer, a television, a cellular phone, or the like. Along display devices there are different types depending on how light is emitted, including an organic light emitting display (OLED) device, which is a self-emitting device, a liquid crystal display (LCD) device, which requires a separate light source, and the like.

As an applicable range of the display device has diversified to be compact for uses such as personal digital assistants, as well as uses for large-sized monitors of computers and televisions, a display device with a large display area and a reduced volume and weight is being studied.

Further, in recent years, a display device including a light emitting diode is attracting attention as a next generation display device. Since the light emitting diode is formed of an inorganic material, rather than an organic material, reliability can be improved so that a lifespan of a display device using the light emitting diode can be longer than that of the liquid crystal display device or the organic light emitting display device. Further, the light emitting diode has a fast-lighting speed, excellent luminous efficiency, and a strong impact resistance so that a stability is excellent and an image having a high luminance can be displayed.

### SUMMARY OF THE DISCLOSURE

An object to be achieved by the present disclosure is to provide a light emitting element which is connected to a panel regardless of a placement direction and a display device including the same.

Another object to be achieved by the present disclosure is to provide a light emitting element which is connectable in various directions and a display device including the same.

Another object to be achieved by the present disclosure is to provide a light emitting element with an improved assembly rate and a display device including the same.

Objects of the present disclosure are not limited to the above-mentioned objects, and other objects, which are not mentioned above, can be clearly understood by those skilled in the art from the following descriptions.

According to an aspect of the present disclosure, there is provided a light emitting element. The light emitting element comprises a semiconductor layer; and a plurality of electrodes which is in contact with a part of the semiconductor layer, wherein the semiconductor layer includes a first semiconductor layer; an emission layer disposed on the first semiconductor layer; and a second semiconductor layer disposed on the emission layer, the plurality of electrodes includes: a plurality of first electrodes which is disposed so as to correspond to a corner of the semiconductor layer; and a second electrode which is spaced apart from the plurality of first electrodes and is disposed in a center portion of a surface of the semiconductor layer.

According to an aspect of the present disclosure, there is provided a display device. The display device comprises a substrate including a plurality of sub pixels; a plurality of transistors disposed on the substrate; and a plurality of light emitting elements which is disposed on the plurality of sub pixels on the plurality of transistors.

According to the present disclosure, an electrode is formed on a front surface of a light emitting element to connect the light emitting element and a display panel regardless of a transferring direction.

According to the present disclosure, a contact failure of the light emitting element and the display panel can be reduced.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIGS. 1A to 1C are views for a light emitting element according to an example embodiment of the present disclosure;

FIGS. 2A to 2C are perspective views for explaining various placements of a light emitting element according to an example embodiment of the present disclosure;

FIGS. 3A to 3K are process diagrams for explaining a manufacturing method of a light emitting element according to an example embodiment of the present disclosure;

FIGS. 4A to 4F are plan views of a light emitting element according to a manufacturing method of a light emitting element according to an example embodiment of the present disclosure;

FIG. 5 is a schematic diagram of a display device according to an example embodiment of the present disclosure;

FIG. 6 is a cross-sectional view of a sub pixel of a display device according to an example embodiment of the present disclosure;

FIG. 7 is a plan view of a sub pixel of a display device according to another example embodiment of the present disclosure;

FIG. 8 is a cross-sectional view taken along A-B of FIG. 7;

FIG. 9 is a plan view of a sub pixel of a display device according to still another example embodiment of the present disclosure; and

FIG. 10 is a cross-sectional view taken along the line C-D of FIG. 9.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

The term “can” fully encompasses all the meanings and coverages of the term “may.”

Hereinafter, a light emitting element and a display device according to example embodiments of the present disclosure will be described in detail with reference to accompanying drawings.

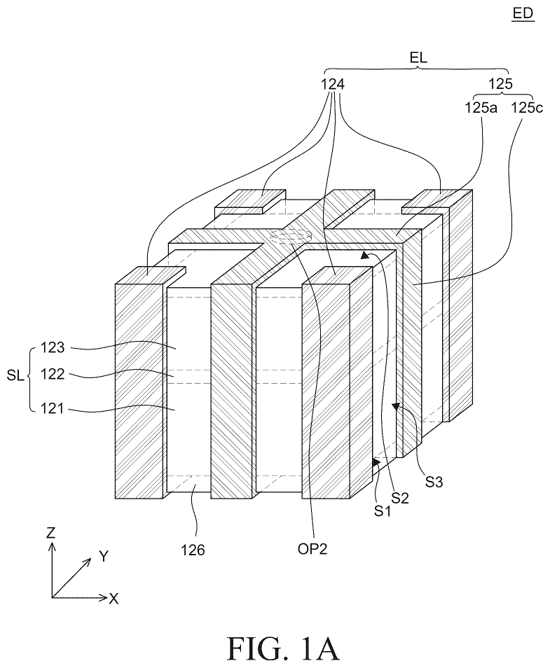

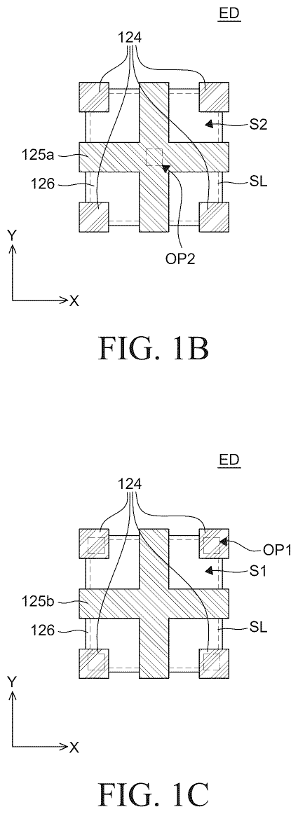

FIGS. 1A to 1C are views for a light emitting element according to an example embodiment of the present disclosure. Particularly, FIG. 1A is a perspective view of a light emitting element ED according to an example embodiment of the present disclosure. FIG. 1B is a plan view of a light emitting element ED according to an example embodiment of the present disclosure. FIG. 1C is a rear view of a light emitting element ED according to an example embodiment of the present disclosure. All components of each light emitting element, and all components of each display device according to all embodiments of the present disclosure are operatively coupled and configured.

Referring to FIGS. 1A to 1C, the light emitting element ED includes a semiconductor layer (or structure) SL, a plurality of electrodes EL, and an encapsulation layer 126.

The semiconductor layer SL of the light emitting element ED can include a first semiconductor layer 121, an emission layer 122, and a second semiconductor layer 123.

Referring to FIGS. 1A to 1C, the first semiconductor layer 121 of the light emitting element ED is disposed and the second semiconductor layer 123 is disposed on the first semiconductor layer 121.

The first semiconductor layer 121 and the second semiconductor layer 123 can be layers formed by doping n-type and p-type impurities into a specific material, respectively. For example, the first semiconductor layer 121 and the second semiconductor layer 123 can be layers respectively doped with n-type and p-type impurities into a material such as gallium nitride (GaN), indium aluminum phosphide (InAlP), or gallium arsenide (GaAs). Further, the p-type impurity can be magnesium (Mg), zinc (Zn), and beryllium (Be), and the n-type impurity can be silicon (Si), germanium, and tin (Sn), but is not limited thereto.

The emission layer 122 is disposed between the first semiconductor layer 121 and the second semiconductor layer 123.

The emission layer 122 is supplied respectively with holes and electrons from the first semiconductor layer 121 and the second semiconductor layer 123 to emit light. The emission layer 122 can be formed by a single layer or a multi-quantum well (MQW) structure, and for example, can be formed of indium gallium nitride (InGaN) or gallium nitride (GaN), but is not limited thereto.

In the meantime, the semiconductor layer SL can have a cubic shape, but is not limited thereto. For example, a horizontal length and a vertical length of each of the first semiconductor layer 121 and the second semiconductor layer 123 are equal to each other and are also equal to a sum of heights of the first semiconductor layer 121, the second semiconductor layer 123, and the emission layer 122, but is not limited thereto.

Referring to FIGS. 1A to 1C, an encapsulation layer 126 which covers a part of the semiconductor layer SL is disposed.

The encapsulation layer 126 can be disposed so as to enclose at least a part of the first semiconductor layer 121, the emission layer 122, and the second semiconductor layer 123. The encapsulation layer 126 can be formed of or include an insulating material to protect the semiconductor layer SL.

The encapsulation layer 126 includes at least one or more first opening OP1 which expose a bottom (or a first) surface of the first semiconductor layer 121 and at least one or more second openings OP2 which expose a top (or a second) surface of the second semiconductor layer 123.

Referring to FIG. 1C, the first opening OP1 is disposed so as to correspond to a corner of the bottom surface of the first semiconductor layer 121. Therefore, the first semiconductor layer 121 and the first electrode 124 are in contact with each other in the first semiconductor layer 121 exposed through the first opening OP1.

Referring to FIG. 1B, the second opening OP2 can be disposed so as to correspond to a center portion of the top surface of the second semiconductor layer 123. Therefore, the second semiconductor layer 123 and the second electrode 125 can be in contact with each other in the second semiconductor layer 123 exposed through the second opening OP2.

Referring to FIGS. 1A to 1C, the light emitting element ED can include a plurality of electrodes EL which can be in contact with a part of the semiconductor layer SL.

The plurality of electrodes EL can include a second electrode 125 and a plurality of first electrodes 124, but is not limited thereto.

The plurality of first electrodes 124 can be disposed so as to correspond to a portion of the light emitting element ED that is apart from a portion of the light emitting element ED that corresponds to the second electrode 125. As shown in FIGS. 1A to 1C, the plurality of first electrodes 124 can be disposed one or more corners of the semiconductor layer SL. Each of the plurality of first electrodes 124 can be disposed so as to cover a vertex of the top surface S2 of the semiconductor layer SL and a vertex of the bottom surface S1 of the semiconductor layer SL.

Referring to FIGS. 1B and 1C together, the plurality of first electrodes 124 can be disposed in portions corresponding to the vertexes of the top surface S2 and the bottom surface S1 of the semiconductor layer SL. Further, referring to FIG. 1A together, each of the plurality of first electrodes 124 can extend from the top surface S2 and the bottom surface S1 of the semiconductor layer SL to cover a side (or third) surface S3 of the semiconductor layer SL.

Referring to FIG. 1A, each of the plurality of first electrodes 124 disposed on the top surface S2 and the bottom surface S1 of the semiconductor layer SL extends to the Z-axis to be disposed on the side surface S3 of the semiconductor layer SL. Accordingly, each of the plurality of first electrodes 124 can be disposed so as to cover the corner of the side surface S3 of the semiconductor layer SL.

The plurality of first electrodes 124 and the first semiconductor layer 121 of the light emitting element ED can be in contact with each other below the first semiconductor layer 121. For example, referring to FIG. 1C, the plurality of first openings OP1 which exposes the first semiconductor layer 121 can be disposed in the encapsulation layer 126 disposed on the bottom surface S1 of the semiconductor layer SL. Therefore, each of the plurality of first electrodes 124 can be in contact with the first semiconductor layer 121 in the plurality of first openings OP1.

Referring to FIG. 1C, the plurality of first openings OP1 can be disposed in a portion of the encapsulation layer 126 corresponding to the corner of the bottom surface of the first semiconductor layer 121. The plurality of first electrodes 124 can be in contact with the first semiconductor layer 121 in a portion corresponding to the corner of the bottom surface of the first semiconductor layer 121.

For example, the first semiconductor layer 121 can be a semiconductor layer doped with an n-type impurity and the first electrode 124 can be a cathode. The first electrode 124 can be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto. Other conductive materials can be used, including one or more conductive adhesive films.

The second electrode 125 can be disposed to be spaced apart from the first electrode 124 and can be disposed in a center portion of the surface of each semiconductor layer SL, but is not limited thereto. The second electrode 125 can be located at any portion of each semiconductor layer SL at a location between adjacent first electrodes 124, for example.

The second electrode 125 can be in contact with the second semiconductor layer 123. For example, referring to FIG. 1B, the second opening OP2 which exposes the second semiconductor layer 123 can be disposed on the top surface S2 of the semiconductor layer SL. Therefore, the second electrode 125 can be in electrical and/or physical contact with the second semiconductor layer 123 in the second opening OP2. Referring to FIG. 1B, the second opening OP2 can be disposed in a portion corresponding to the center portion of the top surface of the second semiconductor layer 123. The second electrode 125 can be in contact with the second semiconductor layer 123 in a portion corresponding to the center portion of the bottom surface of the first semiconductor layer 121, but is not limited thereto. The second opening and/or a contact between the second electrode 125 and the second semiconductor layer 123 can be located anywhere there is overlap between the second electrode 125 and the second semiconductor layer 123.

The second electrode 125 can include a first part 125a, a second part 125b, and a third part 125c. The first part 125a, the second part 125b, and the third part 125c can be disposed on a top surface S2, a bottom surface S1, and a side surface S3 of the semiconductor layer SL, respectively.

Referring to FIGS. 1A and 1B, the first part 125a can be disposed on the top surface S2 of the semiconductor layer SL.

The first part 125a can be disposed at a portion of the top surface S2 of the semiconductor layer SL excluding the vertex. The first part 125a can be disposed in an area corresponding to a center portion of the top surface S2 of the semiconductor layer SL and extend in at least one of the X direction and the Y direction from the center portion of the semiconductor layer SL. For example, the first part 125a of the second electrode 125 can have a cross (+) shape, but is not limited thereto. For example, the first part 125a of the second electrode 125 can be a diamond shape, or an octagonal shape.

Referring to FIGS. 1A and 1C, the second part 125b can be disposed on the bottom surface S1 of the semiconductor layer SL. The second part 125b can be in electrical contact with the second semiconductor layer 123 in the second opening OP2.

The second part 125b can be disposed in a portion of the bottom surface S1 of the semiconductor layer SL excluding the vertex. The second part 125b can be disposed in an area corresponding to a center portion of the bottom surface S1 of the semiconductor layer SL and can extend in at least the X direction and the Y direction from the center portion of the semiconductor layer SL. For example, the second part 125b of the second electrode 125 can have a cross (+) shape, but is not limited thereto. For example, the second part 125b of the second electrode 125 can be a diamond shape, or an octagonal shape.

In the meantime, the first part 125a and the second part 125b can have the same shape, but are not limited thereto. Also, thicknesses of the first part 125a and the second part 125b may can be the same, but can differ also. Additionally, thickness of the plurality of first electrodes 124 on the bottom surface S1 or the top surface S2 can be the same or can differ from each other, and also relative to the first part 125a and/or the second part 125b of the second electrode 125.

Referring to FIG. 1A, the third part 125c can be disposed on the side surface S3 of the semiconductor layer SL. The third part 125c can be disposed in a center portion of the side surface S3 of the semiconductor layer SL and can extend to the Y axis direction, but is not limited thereto. For example, the third part 125c need not be disposed in the center portion of the side surface S3 of the semiconductor layer SL, but can be shifted to a one side or another side of the side surface S3.

The third part 125c can be electrically connected to the first part 125a and the second part 125b. For example, the third part 125c can be integrally formed with the first part 125a and the second part 125b, but is not limited thereto. Further, the third part 125c can be formed to be separated from the first part 125a and the second part 125b. Further, the third part 125c can be formed by a plurality of layers. For example, the third part 125c can be formed by a layer extending from the first part 125a and a layer extending from the second part 125b, but is not limited thereto.

The third part 125c can have a different shape from those of the first part 125a and the second part 125b. For example, referring to FIG. 1A, the third part 125c of the second electrode 125 extends from a corner at which the top surface S2 and the side surface S3 of the semiconductor layer SL meet toward a corner at which the bottom surface S1 and the side surface S3 of the semiconductor layer SL meet and can have a straight shape.

For example, the second semiconductor layer 123 can be a semiconductor layer doped with a p-type impurity and the second electrode 125 can be an anode.

In the meantime, at least one of the plurality of electrodes EL can include a ferromagnetic material. For example, the second electrode 125 can include a ferromagnetic material such as iron (Fe), cobalt (Co), or nickel (Ni) but is not limited thereto. The second electrode 125 can also be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto. The second electrode 125 can include the ferromagnetic material and/or the transparent conductive material at one or more specific locations, such as one or more of the bottom surface S1, the top surface S2 and the side surface S3 of the semiconductor layer SL, or can partially include the ferromagnetic material and/or the transparent conductive material. When a part of the second electrode 125 includes the ferromagnetic material and/or the transparent conductive material, the remainder of the second electrode 125 can be a non-ferromagnetic material, or simply a conductive material.

In the meantime, when the light emitting element ED is a self-assembling light emitting element, the ferromagnetic material can be disposed to easily assemble the light emitting element ED. Therefore, when the light emitting element ED is not a self-assembling light emitting element, the plurality of electrodes EL may not include a ferromagnetic material, but is not limited thereto.

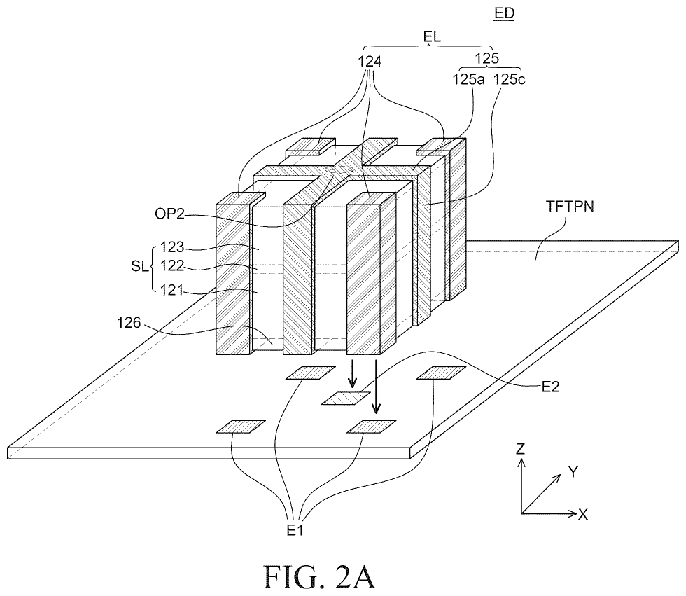

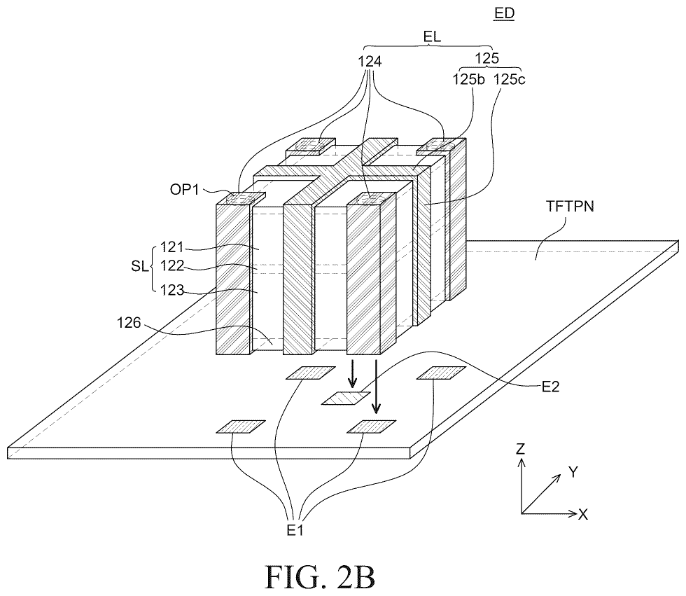

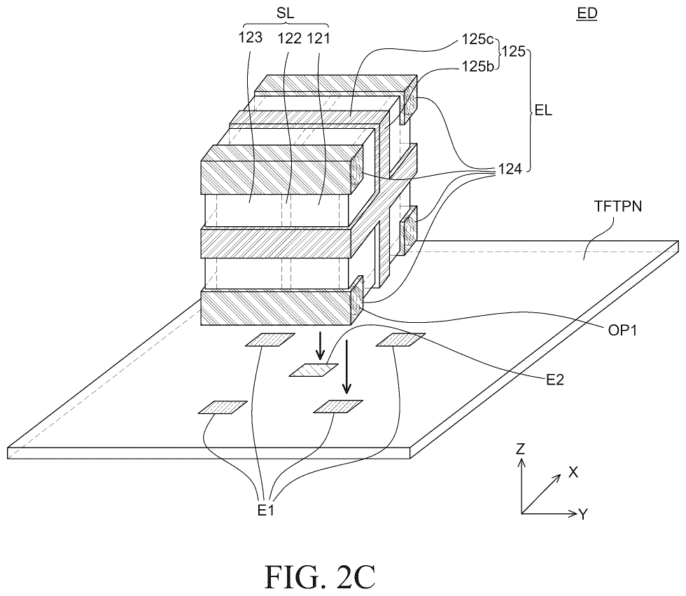

FIGS. 2A to 2C are perspective views for explaining various placements of a light emitting element according to an example embodiment of the present disclosure. FIGS. 2A to 2C are perspective views for explaining various placements of a light emitting element ED disposed on a TFT panel (TFTPN). FIG. 2A is a perspective view when the light emitting element ED of FIG. 1 is disposed in a correct position on the TFT panel TFTPN. FIG. 2B is a perspective view when the light emitting element ED of FIG. 1 is disposed upside down on the TFT panel TFTPN. FIG. 2C is a perspective view when the light emitting element ED of FIG. 1 is disposed to be laid sideways on the TFT panel TFTPN.

The plurality of first panel electrodes E1 and the second panel electrode E2 are disposed on the TFT panel TFTPN. The plurality of first panel electrodes E1 and the second panel electrode E2 are electrodes for driving the light emitting element ED. When the plurality of first panel electrodes E1 and the plurality of first electrodes 124 of the light emitting element ED are in contact with each other and the second panel electrode E2 and the second electrode 125 of the light emitting element ED are in contact with each other, the light emitting element ED can be normally driven.

Referring to FIGS. 2A to 2C, the TFT panel TFTPN is disposed on the X-Y plane. Therefore, the second panel electrode E2 can be disposed in the center portion of the TFT panel TFTPN. The plurality of first panel electrodes E1 can be disposed to be more adjacent to the outside of the TFT panel TFTPN than the second panel electrode E2.

In the meantime, even though in FIGS. 2A to 2C, it is illustrated that the plurality of first panel electrodes E1 can be disposed on the TFT panel TFTPN, a single first panel electrode E1 can be disposed on the TFT panel TFTPN.

Referring to FIG. 2A, the first semiconductor layer 121, the emission layer 122, and the second semiconductor layer 123 of the semiconductor layer SL can be sequentially disposed along the Z direction on the TFT panel TFTPN.

At this time, first electrodes 124 and the second parts 125b of the plurality of the second electrode 125 disposed below the first semiconductor layer 121 can be disposed in positions corresponding to the plurality of first panel electrodes E1 and the second panel electrode E2, respectively. Therefore, the plurality of first electrodes 124 can be in contact with the plurality of first panel electrodes E1 and the second part 125b of the second electrode 125 can be in contact with the second panel electrode E2.

Referring to FIG. 2B, the second semiconductor layer 123, the emission layer 122, and the first semiconductor layer 121 of the semiconductor layer SL are sequentially disposed along the Z direction on the TFT panel TFTPN. For example, the placement of the semiconductor layer SL of the light emitting element ED illustrated in FIG. 2B can be opposite of the lamination order of the semiconductor layer SL of the light emitting element ED illustrated in FIG. 2A.

At this time, the plurality of first electrodes 124 and the first parts 125a of the second electrode 125 disposed below the second semiconductor layer 123 can be disposed in positions corresponding to the plurality of first panel electrodes E1 and the second panel electrode E2, respectively. Therefore, the plurality of first electrodes 124 can be in contact with the plurality of first panel electrodes E1 and the first part 125a of the second electrode 125 can be in contact with the second panel electrode E2.

Referring to FIG. 2C, the second semiconductor layer 123, the emission layer 122, and the first semiconductor layer 121 of the semiconductor layer SL are sequentially disposed along the Y direction on the TFT panel TFTPN.

At this time, first electrodes 124 and the third parts 125c of the plurality of the second electrode 125 disposed on the side surfaces of the second semiconductor layer 123, the emission layer 122, and the first semiconductor layer 121 can be disposed in positions corresponding to the plurality of first panel electrodes E1 and the second panel electrode E2, respectively. Therefore, the plurality of first electrodes 124 can be in contact with the plurality of first panel electrodes E1 and the third part 125c of the second electrode 125 can be in contact with the second panel electrode E2.

With reference to FIGS. 1A to 3D, the light emitting element ED having the semiconductor layer SL and the plurality of electrodes EL can have a structure that is cubical having 6 surfaces, whereby the second electrode 125 has a shape that bisects the semiconductor layer SL in a first direction (e.g., X direction) and bisects the semiconductor layer SL a second direction (e.g., Y direction) that intersects the first direction. The second electrode 125 that bisects the semiconductor layer SL in both the X and Y directions provide 4 quadrants for the semiconductor layer SL. The plurality of first electrodes 124 are provided in the 4 quadrants, respectively. Also, at each of the first surface S1, the second surface S2 and the third surface S3, the second electrode 125 can be interposed between adjacent first electrodes 124 of the plurality of first electrodes 124. Each of the first surface S1, the second surface S2 and the third surface S3 can include plurality of first electrodes 124 and the first electrode 125.

In addition to the entire semiconductor layer SL being provided with 4 quadrants, each of the bottom surface S1 and the top surface S2 can also be provided with 4 quadrants individually by the second electrode 125 that bisects the bottom surface S1 and the top surface S2 in both the X and Y directions, and the plurality of first electrodes 124 can be provided in the 4 quadrants, respectively, of each of the bottom surface S1 and the top surface S2.

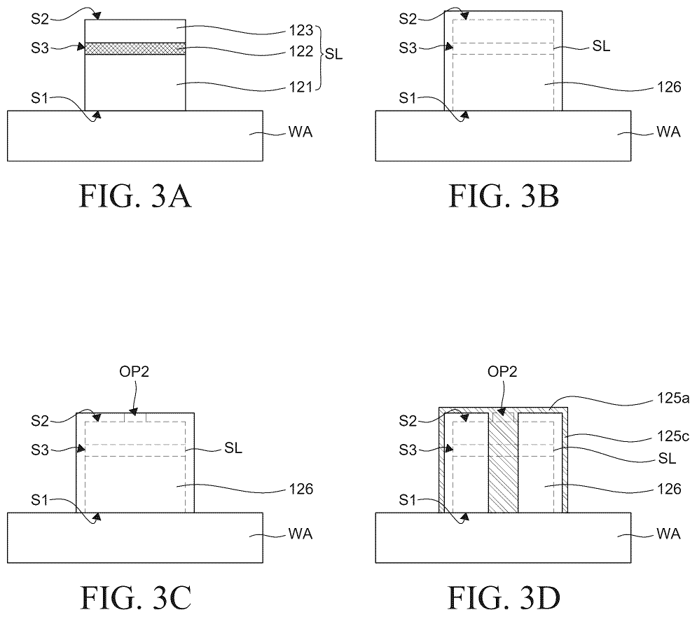

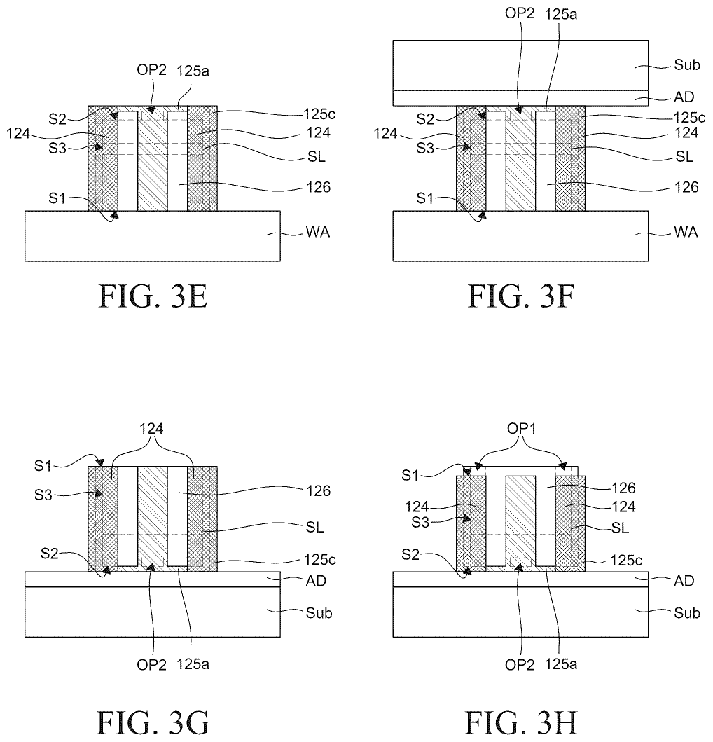

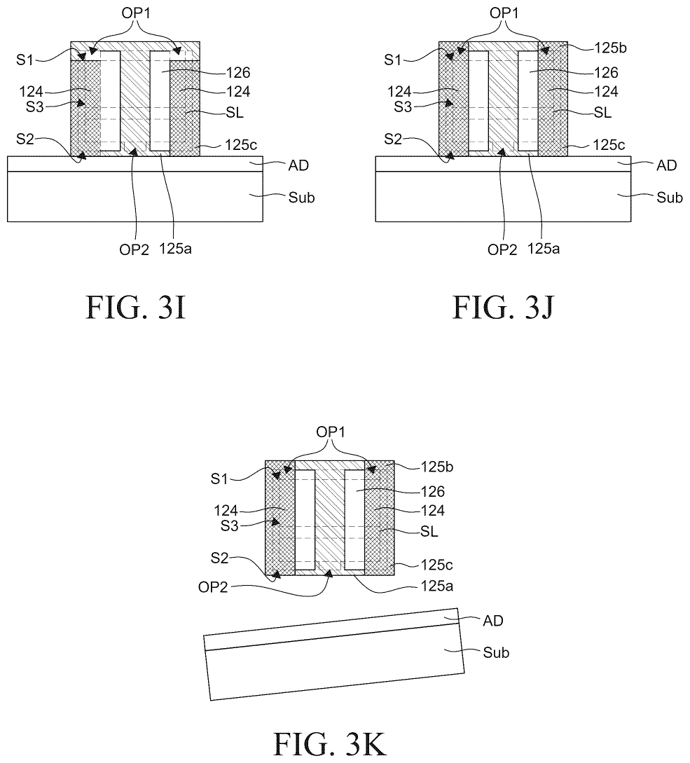

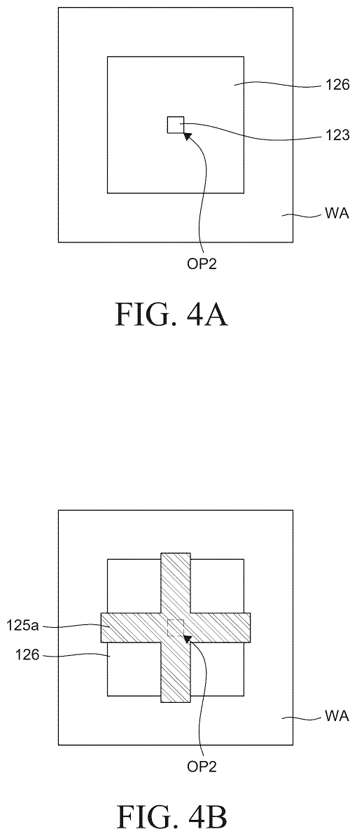

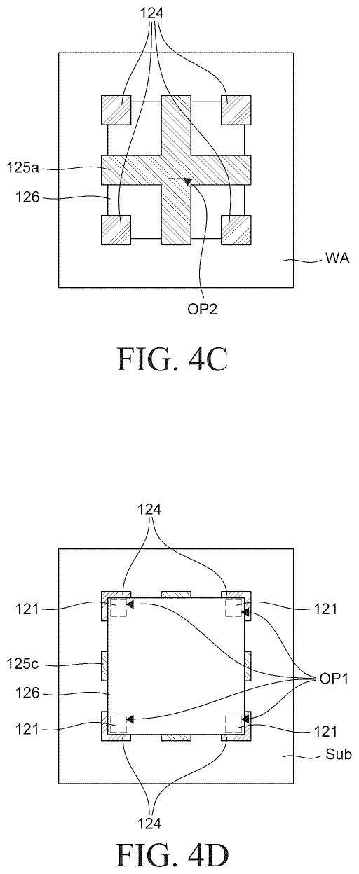

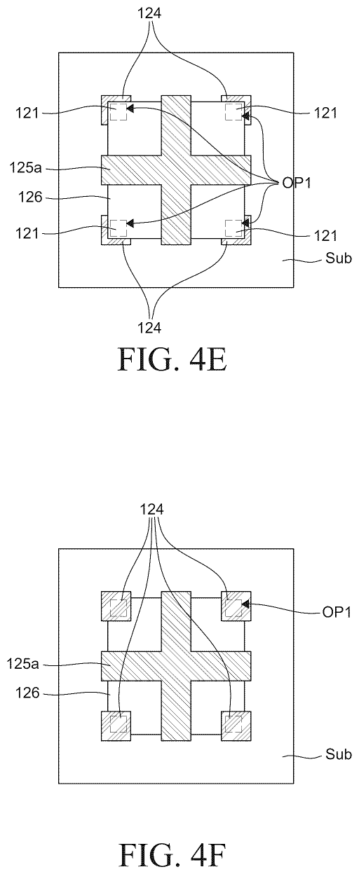

Hereinafter, a manufacturing method of a light emitting element according to an example embodiment of the present disclosure will be described in detail with reference to FIGS. 3A to 4F.

FIGS. 3A to 3K are process diagrams for explaining a manufacturing method of a light emitting element according to an example embodiment of the present disclosure. FIGS. 4A to 4F are plan views according to a manufacturing method of a light emitting element according to an example embodiment of the present disclosure. Particularly, FIGS. 3A to 3K are side views according to a manufacturing method of a light emitting element according to an example embodiment of the present disclosure. FIGS. 4A to 4F are plan views according to a manufacturing method of a light emitting element according to an example embodiment of the present disclosure. For the convenience of illustration, a plan view for a part of FIGS. 3A to 3K is illustrated. FIG. 4A is a plan view of FIG. 3C as seen from the top, FIG. 4B is a plan view of FIG. 3D as seen from the top, FIG. 4C is a plan view of FIG. 3E as seen from the top. Further, FIG. 4D is a plan view of FIG. 3H as seen from the top, FIG. 4E is a plan view of FIG. 31 as seen from the top, and FIG. 4F is a plan view of FIG. 3J as seen from the top.

First, referring to FIG. 3A, after sequentially forming the first semiconductor layer 121, the emission layer 122, and the second semiconductor layer 123 on a wafer WA, a partial area of the first semiconductor layer 121, the emission layer 122, and the second semiconductor layer 123 can be etched to separate the light emitting element ED. Therefore, the first semiconductor layer 121, the emission layer 122, and the second semiconductor layer 123 are formed on the wafer WA to be separated in the unit of light emitting element ED and configure the semiconductor layer SL of the light emitting element ED.

Next, referring to FIG. 3B, an encapsulation layer 126 can be formed on the semiconductor layer SL. Therefore, the encapsulation layer 126 can be formed in an area excluding a surface which can be in contact with the wafer WA of the semiconductor layer SL. For example, the encapsulation layer 126 can be disposed so as to enclose the top surface S2 and the side surface S3 of the semiconductor layer SL. Therefore, the encapsulation layer 126 encloses the side surfaces of the first semiconductor layer 121, the second semiconductor layer 123, and the emission layer 122, and can cover a top surface of the first semiconductor layer 121.

Next, referring to FIGS. 3C and 4A, the second opening OP2 can be formed in the encapsulation layer 126. The encapsulation layer 126 formed on the center portion of the top surface S2 of the semiconductor layer SL is removed to form the second opening OP2. Therefore, one surface of the second semiconductor layer 123 disposed on the top surface S2 of the semiconductor layer SL can be exposed through the second opening OP2.

Next, referring to FIGS. 3D and 4B, the first part 125a and the third part 125c of the second electrode 125 can be formed above the encapsulation layer 126. The first part 125a of the second electrode 125 can be formed on the top surface S2 of the semiconductor layer SL and the third part 125c of the second electrode 125 can be formed on the side surface S3 of the semiconductor layer SL. The first part 125a can be disposed on the top surface S2 of the semiconductor layer SL excluding an area corresponding to the vertex. For example, the first part 125a can be formed to have a cross shape on the top surface S2 of the semiconductor layer SL. At this time, the first part 125a can be in contact with the second semiconductor layer 123 in the second opening OP2. Further, the third part 125c can be formed in an area corresponding to the center portion of the side surface of the semiconductor layer SL.

Next, referring to FIGS. 3E and 4C, the plurality of first electrodes 124 can be formed above the encapsulation layer 126. The plurality of first electrodes 124 can be formed on the top surface S2 and the side surface S3 of the semiconductor layer SL. The plurality of first electrodes 124 can be formed to overlap an area corresponding to a vertex of the top surface S2 of the semiconductor layer SL. For example, each of the plurality of first electrodes 124 can be formed so as to correspond to an outer peripheral area in each of the top surface S2 and the side surface S3 of the semiconductor layer SL. At this time, each of the plurality of first electrodes 124 can be formed to be spaced apart from each other with the first part 125a of the second electrode 125 and the third part 125c of the second electrode 125 therebetween.

Next, referring to FIG. 3F, the semiconductor layer SL in which the plurality of first electrodes 124, the first parts 125a of the second electrode 125, and the third part 125c of the second electrode 125 are formed can be attached to a temporary substrate Sub. The semiconductor layer SL in which the plurality of first electrodes 124, the first parts 125a of the second electrode 125, and the third part 125c of the second electrode 125 are formed can be attached to a temporary substrate Sub by means of the adhesive layer AD. At this time, the plurality of first electrodes 124 and the third parts 125c of the second electrode 125 are attached to the adhesive layer AD.

Next, referring to FIG. 3G, the semiconductor layer SL in which the plurality of first electrodes 124, the first parts 125a of the second electrode 125, and the third part 125c of the second electrode 125 are formed can be separated from the wafer WA. Therefore, the bottom surface S1 of the semiconductor layer SL to which the wafer WA is attached can be exposed onto the temporary substrate Sub. At this time, the plurality of first electrodes 124 and the third part 125c of the second electrode 125 which are formed on the side surface S3 of the semiconductor layer SL are also exposed.

Next, referring to FIGS. 3H and 4D, the encapsulation layer 126 including the plurality of first openings OP1 can be formed on the bottom surface S1 of the semiconductor layer SL. At this time, the encapsulation layer 126 can be formed so as to expose the plurality of first electrodes 124 and the third part 125c of the second electrode 125 which are formed on the side surface S3 of the semiconductor layer SL while covering the entire bottom surface S1 of the semiconductor layer SL. Further, the plurality of first openings OP1 can be formed in the encapsulation layer 126. The encapsulation layer 126 can be removed from a portion corresponding to the vertex of the bottom surface S1 of the semiconductor layer SL to form the plurality of first openings OP1. Therefore, one surface of the first semiconductor layer 121 disposed in a lower portion of the semiconductor layer SL can be exposed through the plurality of first openings OP1. At this time, the encapsulation layer 126 formed on the bottom surface S1 and the side surface S3 of the semiconductor layer SL can be in contact with the encapsulation layer 126 formed on the top surface S2 and the side surface S3 of the semiconductor layer SL. Therefore, the semiconductor layer SL and the encapsulation layer 126 which encloses the top surface S2, the bottom surface S1, and the side surface S3 of the semiconductor layer SL are formed.

Next, referring to FIGS. 31 and 4E, the second part 125b and the third part 125c of the second electrode 125 are formed above the encapsulation layer 126 to form the second electrode 125. The second part 125b of the second electrode 125 can be formed on the bottom surface S1 of the semiconductor layer SL and the third part 125c of the second electrode 125 can be formed on the side surface S3 of the semiconductor layer SL. The second part 125b and the third part 125c are formed excluding an area corresponding to the vertex of the bottom surface S1 of the semiconductor layer SL. For example, the second part 125b can be formed to have a cross shape on the bottom surface S1 of the semiconductor layer SL. Further, the third part 125c can be formed in an area corresponding to the center portion of the side surface S3 of the semiconductor layer SL. At this time, the second part 125b and the third part 125c of the second electrode 125 formed on the bottom surface S1 and the side surface S3 of the semiconductor layer SL can be in contact with the first part 125a and the third part 125c of the second electrode 125 formed on the top surface S2 and the side surface S3 of the semiconductor layer SL. Therefore, the semiconductor layer SL and the second electrode 125 which encloses the top surface S2, the bottom surface S1, and the side surface S3 of the semiconductor layer SL are formed.

Next, referring to FIGS. 3J and 4F, the plurality of first electrodes 124 can be formed above the encapsulation layer 126 to form the light emitting element ED. The plurality of first electrodes 124 can be formed on the bottom surface S1 and the side surface S3 of the semiconductor layer SL. The plurality of first electrodes 124 can be formed to overlap an area corresponding to a vertex of the bottom surface S1 of the semiconductor layer SL. For example, each of the plurality of first electrodes 124 can be formed so as to correspond to an outer peripheral area in each of the bottom surface S1 and the side surface S3 of the semiconductor layer SL. At this time, the plurality of first electrodes 124 can be formed to be spaced apart from each other with the second electrode 125 therebetween. At this time, each of the plurality of first electrodes 124 can be in contact with the first semiconductor layer 121 in the plurality of first openings OP1. At this time, the plurality of first electrodes 124 formed on the bottom surface S1 and the side surface S3 of the semiconductor layer SL can be in contact with the plurality of first electrodes 124 formed on the top surface S2 and the side surface S3 of the semiconductor layer SL. Therefore, the semiconductor layer SL and the plurality of first electrodes 124 which encloses the top surface S2, the bottom surface S1, and the side surface S3 of the semiconductor layer SL are formed and the light emitting element ED can be formed.

Referring to FIG. 3K, the light emitting element ED can be separated from the temporary substrate Sub. Thereafter, the light emitting element ED can be transferred to the display panel or can be assembled on the assembling substrate to be transferred to the display panel, or can be directly assembled on the display panel including an assembling electrode.

The plurality of light emitting elements formed on the wafer can be separated from the wafer to be transferred to the display panel. At this time, the plurality of light emitting elements can be shifted during the process of being transferred to the display panel. Therefore, the plurality of light emitting elements can be erroneously assembled or erroneously transferred to the display panel.

For example, the plurality of light emitting elements separated from the wafer can be transferred to a donor to be transferred to the display panel again. At this time, during both a primary transferring process of transferring the plurality of light emitting elements to the donor and a secondary transferring process of transferring the plurality of light emitting elements attached to the donor to the display panel, there can be problems in that the light emitting element can be laid down or flipped over. For example, in order to transfer the plurality of light emitting elements to the donor and the display panel, forces, such as heat, laser, or pressure are applied, which can cause the shifting of the position of the plurality of light emitting elements.

Further, the plurality of light emitting elements can be transferred to the display panel also using the self-assembling method. At this time, after dispersing the plurality of light emitting elements in the fluid, an electric field can be applied to the assembling electrode to be assembled on an assembling substrate and then the plurality of light emitting elements assembled on the assembling substrate can be transferred to the display panel again. However, a uniform electric field can be applied to the assembling electrode so that it can be very difficult to assemble the plurality of light emitting elements by distinguishing the directions of the plurality of light emitting elements. Accordingly, when the plurality of light emitting elements is flipped over or laid down, the assembly rate of the light emitting element can be degraded or a contact failure or driving failure problem of the display panel and the light emitting element can be caused.

Therefore, the plurality of first electrodes 124 and the second electrode 125 are disposed on all the surfaces of the light emitting element ED according to the example embodiment of the present disclosure. For example, each of the plurality of first electrodes 124 can be disposed in a portion corresponding to vertexes of the top surface S2 and the bottom surface S1 of the semiconductor layer SL and extends from the top surface S2 and the bottom surface S1 of the semiconductor layer SL to cover the corner of the side surface S3. For example, the second electrode 125 can be disposed in a portion excluding vertexes of the top surface S2 and the bottom surface S1 of the semiconductor layer SL and extends from the top surface S2 and the bottom surface S1 of the semiconductor layer SL to cover the side surface S3. Therefore, the second electrode 125 can be disposed in an area corresponding to the center portion, on each of the top surface, the side surface, and the bottom surface of the light emitting element ED and the plurality of first electrodes 124 can be disposed in an area corresponding to the vertex. Therefore, even though the light emitting element ED according to the example embodiment of the present disclosure is flipped over or laid sideways in the position during the process of being transferred to the display panel, the light emitting element can be connected to the display panel. Accordingly, the light emitting element ED can be connected to the display panel regardless of the position of the light emitting element ED so that the light emitting element ED can be normally driven. Therefore, the problem in that the assembly rate of the light emitting element ED is lowered can be solved and the problem of the contact failure or the driving failure of the display panel and the light emitting element ED can be suppressed.

With reference to FIGS. 1A-4F, a plane view shape of the first opening OP1 and a plane view shape of the second opening OP2 are shown as rectangular, but embodiments of the present disclosure are not limited thereto. In various embodiments of the present disclosure, shapes of first opening OP1 or the second opening OP2 can vary, and can correspond to a plane view shape of the plurality of first electrodes 124 or a plane view of the second electrode 125 on the bottom surface S1 or the top surface S2 of the semiconductor layer SL, but embodiments of the present disclosure are not limited thereto. For example, the plane view shapes of the first opening OP1 and the second opening OP2 can be circular, oval, triangular rectangular, polygonal, irregular, or a combination thereof. Similarly, plane view shapes of plurality of first electrodes 124 or the second electrode 125 on the bottom surface S1 or the top surface S2 of the semiconductor layer can vary, including circular, oval, triangular rectangular, polygonal, irregular, or a combination thereof. A triangular plane view shapes of plurality of first electrodes 124 can provide an exposed area on the bottom surface S1 or the top surface S2 to better emit light from the semiconductor layer SL.

With further reference to FIGS. 1A-4F, widths of each of the plurality of first electrodes 124 or the second electrode 125 on the bottom surface S1, the top surface S2, or the side surface S3 are shown as being constant in longitudinal directions of each of the plurality of first electrodes 124 or the second electrode 125, but embodiments of the present disclosure are not limited thereto. For example, the width of each of the plurality of first electrodes 124 or the second electrode 125 along the longitudinal directions thereof can vary, such as becoming thinner towards a middle of each of the plurality of first electrodes 124 or the second electrode 125, which also provide additional exposed areas on the side surface S3 to better emit light from the semiconductor layer SL.

Also, shapes of each of the panel electrodes E1 and E2 can vary, whereby shapes of the panel electrodes E1 and E2 can include shapes that are circular, oval, triangular rectangular, polygonal, irregular, or a combination thereof, and can also be different from each other. In various embodiments of the present disclosure, the shapes of the panel electrodes E1 and E2 can correspond to those of the plurality of first electrodes 124 or the second electrode 125, or can be different.

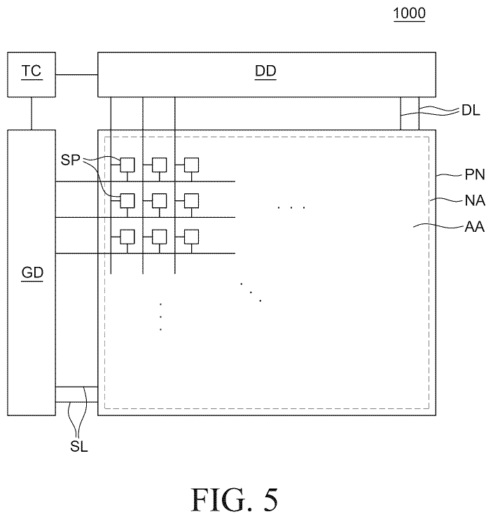

FIG. 5 is a schematic diagram of a display device according to an example embodiment of the present disclosure. In FIG. 5, for the convenience of description, among various components of the display device 1000, a display panel PN, a gate driver GD, a data driver DD, and a timing controller TC are illustrated.

Referring to FIG. 5, the display device 1000 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals supplied from the timing controller TC. Even though in FIG. 5, it is illustrated that one gate driver GD is disposed to be spaced apart from one side of the display panel PN, the number of the gate drivers GD and the placement thereof are not limited thereto.

The data driver DD supplies a data voltage to a plurality of data lines DL according to a plurality of data control signals and image data supplied from the timing controller TC. The data driver DD converts the image data into a data voltage using a reference gamma voltage and can supply the converted data voltage to the plurality of data lines DL.

The timing controller TC aligns image data input from the outside to supply the image data to the data driver DD. The timing controller TC can generate a gate control signal and a data control signal using synchronization signals input from the outside, such as a dot clock signal, a data enable signal, and horizontal/vertical synchronization signals. Further, the timing controller TC supplies the generated gate control signal and data control signal to the gate driver GD and the data driver DD, respectively, to control the gate driver GD and the data driver DD.

The display panel PN can be a configuration which displays images to the user and includes the plurality of sub pixels SP. In the display panel PN, the plurality of scan lines SL and the plurality of data lines DL intersect each other and the plurality of sub pixels SP is connected to intersections of the scan lines SL and the data lines DL.

In the display panel PN, an active area AA and a non-active area NA can be defined.

The active area AA is an area in which images are displayed in the display device 1000. In the active area AA, a plurality of sub pixels SP which configures a plurality of pixels PX and a pixel circuit for driving the plurality of sub pixels SP can be disposed. The plurality of sub pixels SP is a minimum unit which configures the active area AA and n sub pixels SP form one pixel PX. In each of the plurality of sub pixels SP, a thin film transistor for driving the plurality of light emitting elements ED can be disposed. The plurality of light emitting elements ED can be defined in different ways depending on the type of the display panel PN. For example, when the display panel PN is an inorganic light emitting display panel PN, the light emitting element ED can be a light emitting diode (LED) or a micro light emitting diode (LED).

In the active area AA, a plurality of signal lines which transmits various signals to the plurality of sub pixels SP is disposed. For example, the plurality of signal lines can include a plurality of data lines DL which supplies a data voltage to each of the plurality of sub pixels SP and a plurality of scan lines SL which supplies a scan signal to each of the plurality of sub pixels SP. The plurality of scan lines SL extends to one direction in the active area AA to be connected to the plurality of sub pixels SP. Further, the plurality of data lines DL extends to a direction different from the one direction in the active area AA to be connected to the plurality of sub pixels SP. In addition, in the active area AA, a low potential power line and a high potential power line can be further disposed, but are not limited thereto.

The non-active area NA is an area where images are not displayed so that the non-active area NA can be defined as an area extending from the active area AA. In the non-active area NA, a link line which transmits a signal to the sub pixel SP of the active area AA, a pad electrode, or a driving IC, such as a gate driver IC or a data driver IC, can be disposed.

In the meantime, the non-active area NA can be located on a rear surface of the display panel PN, for example, a surface on which the sub pixels SP are not disposed or can be omitted, and is not limited as illustrated in the drawing.

In the meantime, a driver, such as a gate driver GD, a data driver DD, and a timing controller TC, can be connected to the display panel PN in various ways. For example, the gate driver GD can be mounted in the non-active area NA in a gate in panel (GIP) manner or mounted between the plurality of sub pixels SP in the active area AA in a gate in active area (GIA) manner.

For example, the data driver DD and the timing controller TC are formed in separate flexible film and printed circuit board 110. Further, the display panel PN can be electrically connected to the data driver DD and the timing controller TC by bonding the flexible film and printed circuit board 110 to the pad electrode formed in the non-active area NA of the display panel PN

As another example, when the gate driver GD is mounted in the active area AA in the GIA manner and a side line which connects the signal line on the front surface of the display panel PN to the pad electrode on a rear surface of the display panel PN can be formed to bond the flexible film and the printed circuit board 110 onto a rear surface of the display panel PN. At this time, the non-active area NA on the front surface of the display panel PN can be minimized. For example, when the gate driver GD, the data driver DD, and the timing controller TC are connected to the display panel PN as described above, a zero bezel with substantially no bezel can be implemented.

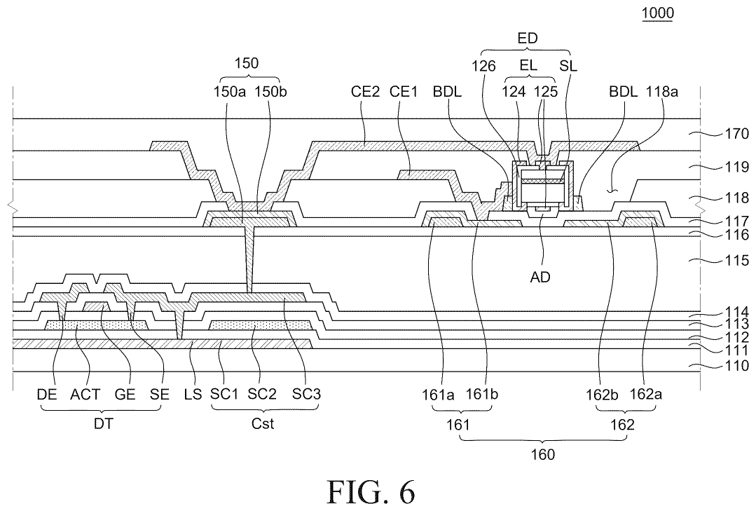

FIG. 6 is a cross-sectional view of a pixel area of a display device according to an example embodiment of the present disclosure.

Referring to FIG. 6, a display device 1000 can include a substrate 110, a light shielding layer LS, a buffer layer 111, a gate insulating layer 112, a first interlayer insulating layer 113. Further, the display device 1000 includes a first passivation layer 114, a first planarization layer 115, a second passivation layer 116, a third passivation layer 117, a second planarization layer 118. Further, the display device 1000 includes a third planarization layer 119, a protection layer 170, an assembly electrode 160, an auxiliary electrode 150, a bonding layer BDL, a light emitting element ED, a driving transistor DT, and a storage capacitor Cst. But embodiments of the display device 1000 are not limited thereto, and different or additional elements can be included.

Referring to FIG. 6, the display device 1000 includes a substrate 110. The substrate 110 is a substrate which supports components disposed above the display device 1000 and can be an insulating substrate. A plurality of sub pixels SP is formed on the substrate 110 to display images. For example, the substrate 110 can be formed of glass or resin. Further, the substrate 110 can include polymer or plastic. In some example embodiments, the substrate 110 can be formed of a plastic material having flexibility, but is not limited thereto.

The plurality of sub pixels SP can be formed on the substrate 110 to form a plurality of rows and a plurality of columns. Each of the plurality of sub pixels SP includes a light emitting element ED and a pixel circuit to independently emit light.

The plurality of sub pixels SP can include a first sub pixel, a second sub pixel, and a third sub pixel which emit different color light. For example, the first sub pixel can be a red sub pixel, the second sub pixel can be a green sub pixel, and the third sub pixel can be a blue sub pixel, but it is not limited thereto, and additional sub pixels or other color light can be provided.

In the first sub pixel, the first light emitting element can be disposed, in the second sub pixel, the second light emitting element can be disposed, and in the third sub pixel, the third light emitting element can be disposed. For example, the first light emitting element can be a red light emitting element, the second light emitting element can be a green light emitting element, and the third light emitting element can be a blue light emitting element, but are not limited thereto.

On the substrate 110, a plurality of wiring lines which supplies various signals to the plurality of sub pixels SP can be disposed. For example, the plurality of data lines DL, the plurality of high potential power lines, and the plurality of low potential power lines extending in the column direction can be disposed on the substrate 110. For example, a plurality of emission control signal lines, a plurality of auxiliary high potential power lines, a plurality of auxiliary low potential power lines, and a plurality of scan lines extending in the row direction are disposed on the substrate 110. Further, the high potential power line extending in the column direction can be electrically connected to the auxiliary high potential power line extending in the row direction through a contact hole. At this time, the emission control signal line transmits an emission control signal to the pixel circuits of the plurality of sub pixels SP to control emission timings of the plurality of sub pixels SP.

The pixel circuit for driving the light emitting element ED can be disposed in each of the plurality of sub pixels SP on the substrate 110. The pixel circuit can include a plurality of thin film transistors and a plurality of capacitors. In FIG. 6, for the convenience of description, a driving transistor DT and a storage capacitor Cst, among configurations of the pixel circuit, are illustrated. However, the pixel circuit can further include a switching transistor, a sensing transistor, and an emission control transistor, but is not limited thereto.

The light shielding layer LS can be disposed on the substrate 110 in each of the plurality of sub pixels SP. The light shielding layer LS blocks light which is incident to the transistor from the lower portion of the substrate 110 to minimize a leakage current. For example, the light shielding layer LS blocks light incident onto the active layer ACT of the driving transistor DT.

In each of the plurality of sub pixels SP, a first capacitor electrode SC1 can be disposed on the substrate 110. The first capacitor electrode SC1 can form a storage capacitor Cst together with the other capacitor electrode. The first capacitor electrode SC1 can be integrally formed with the light shielding layer LS.

The buffer layer 111 can be disposed on the light shielding layer LS and the first capacitor electrode SC1. The buffer layer 111 can reduce permeation of moisture or impurities through the substrate 110. The buffer layer 111 can be configured by a single layer or a double layer of silicon oxide (SiOx) or silicon nitride (SiNx), but is not limited thereto. However, the buffer layer 111 can be omitted depending on a type of substrate 110 or a type of transistor, but is not limited thereto.

The driving transistor DT can be disposed on the buffer layer 111 in each of the plurality of sub pixels SP. The driving transistor DT can be a transistor which supplies a driving current to the light emitting element ED. The driving transistor DT can be turned on to control a driving current flowing to the light emitting element ED.

The driving transistor DT can include an active layer ACT, a gate electrode GE, a source electrode SE, and a drain electrode DE, but is not limited thereto.

The active layer ACT can be disposed on the buffer layer 111. The active layer ACT can be formed of a semiconductor material, such as an oxide semiconductor, amorphous silicon, or polysilicon, but is not limited thereto.

The gate insulating layer 112 can be disposed on the active layer ACT. The gate insulating layer 112 can be an insulating layer which insulates the active layer ACT from the gate electrode GE and can be configured by a single layer or a double layer of silicon oxide (SiOx) or silicon nitride (SiNx), but is not limited thereto. In the meantime, even though in FIG. 6, it is illustrated that the gate insulating layer 112 is disposed on the entire substrate 110, it is not limited thereto and can be disposed so as to overlap only the gate electrode GE.

The gate electrode GE can be disposed on the gate insulating layer 112. The gate electrode GE can be configured by a conductive material, such as copper (Cu), aluminum (Al), molybdenum (Mo), nickel (Ni), titanium (Ti), chrome (Cr), or an alloy thereof, but is not limited thereto.

The first interlayer insulating layer 113 can be disposed on the gate electrode GE. In the first interlayer insulating layer 113, a contact hole through which the source electrode SE and the drain electrode DE are connected to the active layer ACT can be formed. The first interlayer insulating layer 113 can be an insulating layer which protects components below the first interlayer insulating layer 113 and can be configured by a single layer or a double layer of silicon oxide (SiOx) or silicon nitride (SiNx), but is not limited thereto.

The source electrode SE and the drain electrode DE which are electrically connected to the active layer ACT are disposed on the first interlayer insulating layer 113. The drain electrode DE can be electrically connected to the active layer ACT and the high potential power line and the source electrode SE can be electrically connected to the active layer ACT and the light emitting element ED. The source electrode SE and the drain electrode DE can be configured by a conductive material, such as copper (Cu), aluminum (Al), molybdenum (Mo), nickel (Ni), titanium (Ti), chrome (Cr), or an alloy thereof, but are not limited thereto.

The second capacitor electrode SC2 can be disposed on the gate insulating layer 112. The second capacitor electrode SC2 can be one of electrodes which form the storage capacitor Cst and can be disposed to overlap the first capacitor electrode SC1. The second capacitor electrode SC2 can be integrally formed with the gate electrode GE of the driving transistor DT to be electrically connected to the gate electrode GE, but is not limited thereto. The first capacitor electrode SC1 and the second capacitor electrode SC2 can be disposed to be spaced apart from each other with the buffer layer 111 and the gate insulating layer 112 therebetween.

The third capacitor electrode SC3 can be disposed on the first interlayer insulating layer 113. The third capacitor electrode SC3 can be an electrode which forms the storage capacitor Cst and can be disposed to overlap the first capacitor electrode SC1 and the second capacitor electrode SC2. The third capacitor electrode SC3 can be integrally formed with the source electrode SE of the driving transistor DT to be electrically connected to the source electrode SE. Further, the source electrode SE can be electrically connected to the first capacitor electrode SC1 through a contact hole formed in the first interlayer insulating layer 113, the gate insulating layer 112, and the buffer layer 111. Therefore, the first capacitor electrode SC1 and the third capacitor electrode SC3 can be electrically connected to the source electrode SE of the driving transistor DT.

The storage capacitor Cst stores a potential difference between the gate electrode GE and the source electrode SE of the driving transistor DT while the light emitting element ED emits light, so that a constant current can be supplied to the light emitting element ED. The storage capacitor Cst can include a first capacitor electrode SC1, a second capacitor electrode SC2, and a third capacitor electrode SC3. The first capacitor electrode can be formed on the substrate 110 and can be connected to the source electrode SE. The second capacitor electrode SC2 can be formed on the buffer layer 111 and the gate insulating layer 112 and the third capacitor electrode SC3 can be formed on the first interlayer insulating layer 113 and can be connected to the source electrode SE. Further, the voltage between the gate electrode GE and source electrode SE of the driving transistor DT can be stored.

The first passivation layer 114 can be disposed on the driving transistor DT and the storage capacitor Cst. The first passivation layer 114 can be an insulating layer which protects components below the first passivation layer 114 and can be configured by a single layer or a double layer of silicon oxide (SiOx) or silicon nitride (SiNx), but is not limited thereto.

The first planarization layer 115 can be disposed on the first passivation layer 114. The first planarization layer 115 can planarize an upper portion of the substrate 110 on which the driving transistor DT and the storage capacitor Cst are disposed. The first planarization layer 115 can be configured by a single layer or a double layer, and for example, can be formed of photoresist or an acrylic-based organic material, but is not limited thereto.

The second passivation layer 116 can be disposed on the first planarization layer 115. The second passivation layer 116 can be an insulating layer which protects components below the second passivation layer 116 and can be configured by a single layer or a double layer of silicon oxide (SiOx) or silicon nitride (SiNx), but is not limited thereto.

The auxiliary electrode 150 and the plurality of assembly electrodes 160 can be disposed on the second passivation layer 116.

The auxiliary electrode 150 can be an electrode which electrically connects the driving transistor DT and the second connection electrode CE2. The auxiliary electrode 150 can be electrically connected to the source electrode SE which also serves as the third capacitor electrode SC3 through a contact hole formed in the second passivation layer 116, the first planarization layer 115, and the first passivation layer 114.

The auxiliary electrode 150 can have a double layered structure including a first connection layer 150a and a second connection layer 150b. The first connection layer 150a can be disposed on the second passivation layer 116 and the second connection layer 150b which covers the first connection layer 150a can be disposed. The second connection layer 150b can be disposed to enclose all a top surface and side surfaces of the first connection layer 150a.

The second connection layer 150b can be formed of a material which is more resistant to corrosion than the first connection layer 150a. When the display device 1000 is manufactured, the short defect due to the migration between the first connection layer 150a and the adjacent wiring line can be minimized. For example, the first connection layer 150a can be formed of a conductive material, such as copper (Cu) or chrome (Cr). Further, the second connection layer 150b can be formed of molybdenum (Mo) or titanium molybdenum (MoTi), but are not limited thereto.

A plurality of assembly electrodes 160 can be disposed on the second passivation layer 116.

The assembly electrode 160 can include a first assembly electrode 161 and a second assembly electrode 162.

The plurality of first assembly electrodes 161 and the plurality of second assembly electrodes 162 can extend in the column direction in each of the plurality of sub pixels SP and can be disposed to be spaced apart from each other at certain intervals.

The first assembly electrode 161 and the second assembly electrode 162 can be disposed so as to overlap the light emitting element ED. First, the first assembly electrode 161 can be disposed in an area corresponding to one side of the light emitting element ED. The first assembly electrode 161, among the assembly electrodes 160, can be disposed in an area overlapping the low potential power line to be electrically connected to the low potential power line.

The low potential power line can be a wiring line which transmits a low potential power voltage to the light emitting element ED. The low potential power line can extend in the column direction in each of the plurality of sub pixels SP. For example, the low potential power line can be disposed in each of the plurality of sub pixels SP.

The second assembly electrode 162 can be disposed in an area which is spaced apart from the first assembly electrode 161 and corresponds to the other side of the light emitting element ED.

The first assembly electrode 161 and the second assembly electrode 162 can be disposed so as to overlap the plurality of first electrodes 124 of the light emitting element ED and the second electrode 125 of the light emitting element ED can be disposed between the first assembly electrode 161 and the second assembly electrode 162.

Each of the plurality of assembly electrodes 160 can include conductive layers 161a and 162a disposed on the second passivation layer 116 and clad layers 161b and 162b which can be disposed on the conductive layers 161a and 162a and cover all the top surfaces and side surfaces of the conductive layers 161a and 162a.

The first assembly electrode 161 can include the first conductive layer 161a and the first clad layer 161b and the second assembly electrode 162 can include the second conductive layer 162a and the second clad layer 162b.

The first conductive layer 161a and the second conductive layer 162a need not overlap the light emitting element ED. For example, ends of the first conductive layer 161a and the second conductive layer 162a can be disposed at the outside from the end of the light emitting element ED.

The first clad layer 161b of the first assembly electrode 161 can be disposed so as to cover the top surface and the side surface of the first conductive layer 161a. Further, the second clad layer 162b of the second assembly electrode 162 can be disposed so as to cover the top surface and the side surface of the second conductive layer 162a. At this time, the first clad layer 161b and the second clad layer 162b extend to a center portion of the light emitting element ED from ends of the first conductive layer 161a and the second conductive layer 162a to overlap the light emitting element ED.

The first conductive layer 161a and the second conductive layer 162a can be formed of the same material by the same process as the first connection layer 150a of the auxiliary electrode 150. For example, the first conductive layer 161a and the second conductive layer 162a can be formed of a conductive material, such as copper (Cu) and chrome (Cr). Further, the first clad layer 161b and the second clad layer 162b can be formed of the same material by the same process as the second connection layer 150b of the auxiliary electrode 150. For example, the first clad layer 161b and the second clad layer 162b can be formed of a material which is more resistant to corrosion than the first conductive layer 161a and the second conductive layer 162a, for example, molybdenum (Mo) or titanium molybdenum (MoTi), but is not limited thereto.

The third passivation layer 117 can be disposed on the auxiliary electrode 150 and the assembly electrode 160. The third passivation layer 117 can be an insulating layer which protects components below the third passivation layer 117 and can be configured by a single layer or a double layer of silicon oxide (SiOx) or silicon nitride (SiNx), but is not limited thereto.

A partial area of the third passivation layer 117 can be open in an area adjacent to the plurality of light emitting elements ED. For example, an area of the third passivation layer 117 which is adjacent to one side surface, between both side surfaces of the plurality of light emitting elements ED can be open. For example, the third passivation layer 117 can expose a part of top surface of the first assembly electrode 161 in an area adjacent to one side surface of the plurality of light emitting elements ED.

The adhesive layer AD can be disposed on the third passivation layer 117. The adhesive layer AD can be disposed so as to overlap the light emitting element ED and also overlap a part of the assembly electrode 160. The adhesive layer AD can be an organic film which temporarily fixes the light emitting element ED during the self-assembling process of the light emitting element ED. When the display device 1000 is manufactured, if an organic film which covers the light emitting element ED is formed, a part of the organic film can be filled in a space between the light emitting element ED and the third passivation layer 117 and the assembly electrode 160 to temporarily fix the light emitting element ED onto the third passivation layer 117 and the assembly electrode 160. Thereafter, even though the organic film is removed, a part of the organic film which permeates under the light emitting element ED remains without being removed to serve as an adhesive layer. The adhesive layer AD can be formed of an organic material, for example, photoresist or an acrylic-based organic material, but is not limited thereto.

One or more light emitting elements ED can be disposed in one or more sub pixels SP on the adhesive layer AD. The light emitting element ED is an element which emits light by the current. The light emitting element ED can include a light emitting element ED which emits red light, green light, and blue light and implement various color light including white by a combination thereof, but is not limited thereto. Further, various color light can be implemented using the light emitting element ED which emits specific color light and a light conversion member which converts light from the light emitting element ED into another color light.

Referring to FIG. 6, the light emitting element ED can include a first semiconductor layer 121, an emission layer 122, a second semiconductor layer 123, a plurality of first electrodes 124, a second electrode 125, and an encapsulation layer 126, but is not limited thereto.

Even though in FIG. 6, as the plurality of light emitting elements ED, the light emitting elements ED which have been described with reference to FIGS. 1 to 2C can be applied. The plurality of light emitting elements ED has been described in detail with reference to FIGS. 1 to 2C, so that a redundant description will be omitted.

The second planarization layer 118 can be disposed on the third passivation layer 117. The second planarization layer 118 can include a plurality of openings 118a in which each of the plurality of light emitting elements ED is seated. The plurality of openings 118a can be disposed in each of the plurality of sub pixels SP. For example, the number of openings 118a can be the same as the number of light emitting elements ED disposed in one sub pixel SP.

The plurality of openings 118a can be a portion in which the plurality of light emitting elements ED is seated and can be also referred to as pockets. The plurality of openings 118a can be formed so as to overlap the plurality of assembly electrodes 160. One opening 118a can overlap an area between one pair of assembly electrodes 160 disposed to be adjacent to each other in one sub pixel SP. For example, the first clad layer 161b and the second clad layer 162b of one pair of assembly electrodes 160 can overlap the opening 118a.

The second planarization layer 118 can be configured by a single layer or a double layer, and for example, can be formed of photoresist or an acrylic-based organic material, but is not limited thereto.

Further, the second planarization layer 118 can be disposed so as to enclose a part of a side surface of the plurality of light emitting elements ED.

The first connection electrode CE1 can be disposed on the second planarization layer 118. The first connection electrode CE1 can be disposed on the side surface of the light emitting element ED to electrically connect the light emitting element ED and the assembly electrode 160. The first connection electrode CE1 can be disposed so as to enclose at least a part of the first semiconductor layer 121 and the plurality of first electrodes 124 of the light emitting element ED in an area overlapping the first assembly electrode 161. For example, the first connection electrode CE1 can be in contact with the plurality of first electrodes 124 disposed in a lower portion of the light emitting element ED.

At this time, the first connection electrode CE1 can be electrically connected to the first assembly electrode 161 exposed by the third passivation layer 117 in an area in which the third passivation layer 117 can be open. Further, the first connection electrode CE1 extends onto the second planarization layer 118 on the plurality of first electrodes 124 of the light emitting element ED.

In the meantime, the plurality of first electrodes 124 of the light emitting element ED can be electrically connected to the first assembly electrode 161 and be not connected to the second assembly electrode 162 to be directly insulated from the second assembly electrode 162, but is not limited thereto. For example, even though in FIG. 6, it is illustrated that the first connection electrode CE1 is not disposed on the other side surface of the light emitting element ED, it is not limited thereto. Further, the first connection electrode CE1 can be disposed so as to enclose the side surface of the light emitting element ED. Therefore, the first connection electrode CE1 can be electrically connected to both the first assembly electrode 161 and the second assembly electrode 162, but is not limited thereto.

In the meantime, the first connection electrode CE1 can be connected to the plurality of first electrodes 124 of the light emitting element ED, through the bonding layer BDL. For example, the bonding layer BDL can be in contact with the side surface of the plurality of first electrodes 124.

The bonding layer BDL can fix the plurality of light emitting elements ED which is seated in the plurality of openings 118a. Further, the bonding layer BDL can include a conductive material to electrically connect the first connection electrode CE1 and the plurality of first electrodes 124 of the light emitting element ED.

The third planarization layer 119 can be disposed on the light emitting element ED and the first connection electrode CE1. The third planarization layer 119 planarizes an upper portion of the substrate 110 in which the light emitting element ED is disposed and can fix the light emitting element ED onto the substrate 110 together with the adhesive layer AD.

Therefore, the third planarization layer 119 can be disposed to be in contact with the first connection electrode CE1 on one side surface of the light emitting element ED and can be disposed to be in contact with a side surface of the light emitting element on the other side surface of the light emitting element ED.

In the meantime, even though in the drawing, it is illustrated that the third planarization layer 119 is a single layer, it is not limited thereto. Further, the third planarization layer 119 can be configured by a single layer or a double layer, and for example, can be formed of photoresist or an acrylic-based organic material, but is not limited thereto.

The second connection electrode CE2 can be disposed on the third planarization layer 119. The second connection electrode CE2 can be disposed on a plane different from that of the first connection electrode CE1.

The second connection electrode CE2 can be an electrode which electrically connects the plurality of light emitting elements ED and the auxiliary electrode 150. Referring to FIG. 6, the second connection electrode CE2 can be electrically connected to the auxiliary electrode 150 and the driving transistor DT through a contact hole formed in the second planarization layer 118.

The second connection electrode CE2 can be formed of a conductive material, for example, a transparent conductive material, such as indium tin oxide (ITO) or indium zinc oxide (IZO), but is not limited thereto.

The second connection electrode CE2 can be in contact with the second electrode 125 of the light emitting element ED. For example, the second connection electrode CE2 can be disposed above the light emitting element ED to be in contact with the second electrode 125 disposed in an upper portion of the light emitting element ED.

The protection layer 170 can be disposed on the second connection electrode CE2. The protection layer 170 can be a layer for protecting components below the protection layer 170, and can be configured by a single layer or a double layer of translucent epoxy, silicon oxide (SiOx) or silicon nitride (SiNx), but is not limited thereto.

In the meantime, a black matrix can further be disposed on the third planarization layer 119. The black matrix can be disposed between the plurality of sub pixels SP on the third planarization layer 119 to reduce color mixture between the plurality of sub pixels SP. Further, the black matrix covers a part in which the auxiliary electrode 150 and the second connection electrode CE2 are connected to suppress light leakage from the corresponding portion. The black matrix can be formed of an opaque material and for example, can be formed of black resin, but is not limited thereto.

In the light emitting element ED according to the example embodiment of the present disclosure and the display device 1000 including the same, the plurality of first electrodes 124 and the second electrode 125 are disposed on all the surfaces of the light emitting element ED. Therefore, the light emitting element ED can be connected to the display panel PN regardless of the position of the light emitting element ED so that the lowering of the assembly rate of the light emitting element ED can be improved. Further, the problems of the contact failure or the driving failure of the display panel PN and the light emitting element ED can be suppressed.

In the light emitting element ED according to the example embodiment of the present disclosure and the display device 1000 including the same, the light emitting element ED can be assembled by the self-assembly method. Therefore, the uniform electric field can be applied to the assembly electrode so that even though the plurality of light emitting elements ED is flipped over or laid down, the light emitting element ED can be connected to the display panel PN. Therefore, the lowering of the assembly rate of the light emitting element ED and the contact failure or the driving failure of the display panel PN and the light emitting element ED can be improved.

Further, the first connection electrode CE1 and the second connection electrode CE2 which connect the driving transistor DT and the power line VDD are disposed on the side surface of the light emitting element ED and above the light emitting element ED. Therefore, the first connection electrode CE1 and the second connection electrode CE2 can be electrically connected to the plurality of first electrodes 124 and the second electrode 125 disposed on the side surface of the light emitting element ED or above the light emitting element ED. Accordingly, in the light emitting element ED according to the example embodiment of the present disclosure and the display device 1000 including the same, the light emitting element ED can be connected with a lateral structure.

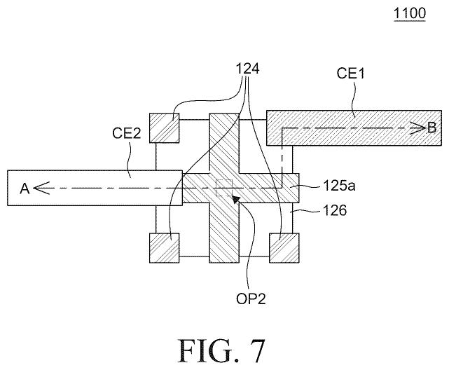

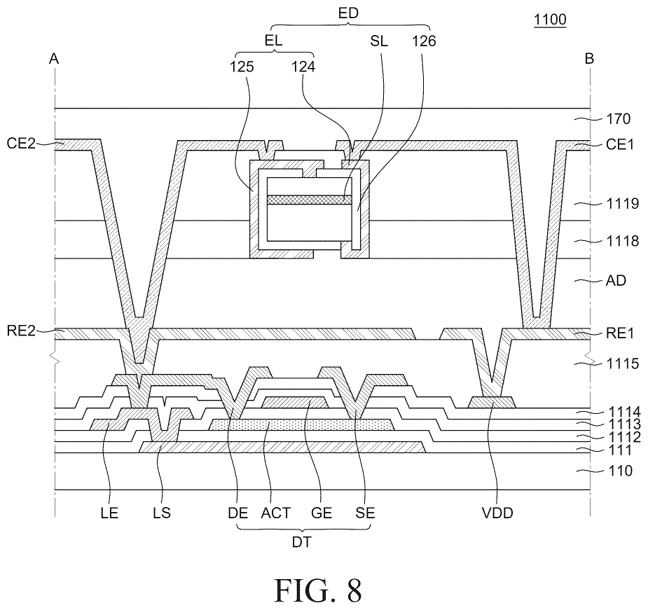

FIG. 7 is a plan view of a sub pixel of a display device according to another example embodiment of the present disclosure. FIG. 8 is a cross-sectional view taken along A-B of FIG. 7. In FIG. 8, for the convenience of illustration, the light emitting element ED, the first connection electrode CE1, and the second connection electrode CE2 are illustrated.

Referring to FIGS. 7 and 8, in each of the plurality of sub pixels SP of the display device 1100 according to another example embodiment of the present disclosure, a substrate 110, a buffer layer 111, a gate insulating layer 1112, a first interlayer insulating layer 1113, a second interlayer insulating layer 1114, a first planarization layer 1115, an adhesive layer AD, a second planarization layer 1118, a third planarization layer 1119, a protection layer 170, a driving transistor DT, a light emitting element ED, a first reflection electrode RF1, a second reflection electrode RE2, a first connection electrode CE1, a second connection electrode CE2, a light shielding layer LS, and an auxiliary line LE are disposed.

The light shielding layer LS and the buffer layer 111 are disposed in each of the plurality of sub pixels SP on the substrate 110.

The driving transistor DT can be disposed on the buffer layer 111. The driving transistor DT includes an active layer ACT, a gate electrode GE, a source electrode SE, and a drain electrode DE.

The active layer ACT can be disposed on the buffer layer 111. The active layer ACT can be formed of a semiconductor material, such as an oxide semiconductor, amorphous silicon, or polysilicon, but is not limited thereto.

The gate insulating layer 1112 can be disposed on the active layer ACT. In the meantime, even though in FIG. 8, it is illustrated that the gate insulating layer 1112 is disposed on the entire substrate 110, it is not limited thereto and can be disposed so as to overlap only the gate electrode GE.

The gate electrode GE can be disposed on the gate insulating layer 1112.

The first interlayer insulating layer 1113 and the second interlayer insulating layer 1114 can be disposed on the gate electrode GE. In the first interlayer insulating layer 1113 and the second interlayer insulating layer 1114, a contact hole through which the source electrode SE and the drain electrode DE are connected to the active layer ACT is formed.

The source electrode SE and the drain electrode DE which are electrically connected to the active layer ACT can be disposed on the second interlayer insulating layer 1114.

In the meantime, in the present specification, it is described that the first interlayer insulating layer 1113 and the second interlayer insulating layer 1114, for example, a plurality of insulating layers can be disposed between the gate electrode GE and the source electrode SE and the drain electrode DE. However, only one insulating layer can optionally be disposed between the gate electrode GE and the source electrode SE and the drain electrode DE.

Further, as illustrated in FIG. 8, when a plurality of insulating layers, such as the first interlayer insulating layer 1113 and the second interlayer insulating layer 1114, can be disposed between the gate electrode GE and the source electrode SE and the drain electrode DE, an electrode can additionally be formed between the first interlayer insulating layer 1113 and the second interlayer insulating layer 1114. The additionally formed electrode can form a capacitor with the other configuration disposed below first interlayer insulating layer 1113 or above the second interlayer insulating layer 1114.

The auxiliary line LE can be disposed on the gate insulating layer 1112. The auxiliary line LE can be an electrode which electrically connects the light shielding layer LS below the buffer layer 111 to any one of the source electrode SE and the drain electrode DE on the second interlayer insulating layer 1114. For example, the light shielding layer LS can be electrically connected to any one of the source electrode SE or the drain electrode DE through the auxiliary line LE so as not to operate as a floating gate. Therefore, fluctuation of a threshold voltage of the driving transistor DT caused by the floated light shielding layer LS can be minimized. Even though in the drawing, the light shielding layer LS is connected to the drain electrode DE, the light shielding layer LS can also be connected to the source electrode SE, but is not limited thereto.

The power line VDD can be disposed on the second interlayer insulting layer 1114. The power line VDD can be electrically connected to the light emitting element ED together with the driving transistor DT to allow the light emitting element ED to emit light. The power line VDD can be configured by a conductive material such as copper (Cu), aluminum (Al), molybdenum (Mo), nickel (Ni), titanium (Ti), chrome (Cr), or an alloy thereof, but is not limited thereto.

The first planarization layer 1115 can be disposed on the driving transistor DT and the power line VDD. The first planarization layer 1115 can planarize an upper portion of the substrate 110 on which the driving transistor DT is disposed.

A first reflection electrode RE1 and a second reflection electrode RE2 which are spaced apart from each other can be disposed on the first planarization layer 1115. The first reflection electrode RE1 and the second reflection electrode RE2 can function as a reflection plate which reflects light emitted from the light emitting element ED to the upper portion of the light emitting element ED. The first reflection electrode RE1 and the second reflection electrode RE2 are formed of a conductive material having an excellent reflection property to reflect light emitted from the light emitting element ED to the upper portion of the light emitting element ED.

The first reflection electrode RE1 can electrically connect the power line VDD and the light emitting element ED. The first reflection electrode RE1 can be connected to the power line VDD through a contact hole formed in the first planarization layer 1115 and can be electrically connected to the plurality of first electrodes 124 of the light emitting element ED through a first connection electrode CE1 to be described below.

The second reflection electrode RE2 can electrically connect the driving transistor DT and the light emitting element ED. The second reflection electrode RE2 can be connected to the source electrode SE or the drain electrode DE of the driving transistor DT through a contact hole formed in the first planarization layer 1115. Further, the second reflection electrode RE2 can be electrically connected to the second electrode 125 of the light emitting electrode ED through a second connection electrode CE2 to be described below.

The adhesive layer AD can be disposed on the first reflection electrode RE1 and the second reflection electrode RE2. In the adhesive layer AD, a contact hole through which the first connection electrode CE1 is connected to the first reflection electrode RE1 and a contact hole through which the second connection electrode CE2 is connected to the second reflection electrode RE2 can be disposed. The adhesive layer AD can be coated on the entire substrate 110 to fix the light emitting element ED disposed on the adhesive layer AD. For example, the adhesive layer AD can be in contact with the plurality of first electrodes 124 and the second electrode 125 disposed below the plurality of light emitting elements ED.

The plurality of light emitting elements ED can be disposed in each of the plurality of sub pixels SP on the adhesive layer AD.

Referring to FIG. 8, the light emitting element ED includes a first semiconductor layer 121, an emission layer 122, a second semiconductor layer 123, a plurality of first electrodes 124, a second electrode 125, and an encapsulation layer 126. Even though in FIG. 8, as the plurality of light emitting elements ED, the light emitting elements ED which have been described with reference to FIGS. 1 to 2C can be applied. The plurality of light emitting elements ED has been described in detail with reference to FIGS. 1 to 2C, so that a redundant description will be omitted.

In the meantime, the adhesive layer AD can be filled in an area between the plurality of first electrodes 124 and the second electrode 125 below the light emitting element ED. For example, referring to FIG. 8, the adhesive layer AD can be filled between the plurality of first electrodes 124 and the second electrode 125 and can be in contact with the encapsulation layer 126 disposed below the light emitting element ED, but is not limited thereto.

The second planarization layer 1118 and the third planarization layer 1119 can be disposed on the adhesive layer AD and the plurality of light emitting elements ED.

The second planarization layer 1118 can overlap a part of side surfaces of the plurality of light emitting elements ED to fix and protect the plurality of light emitting elements ED. For example, the second planarization layer 1118 can cover a lower portion of the plurality of light emitting elements ED and can suppress the contact and short defects of the first connection electrode CE1 and the second connection electrodes CE2 and the light emitting element ED.

The third planarization layer 1119 can cover upper portions of the second planarization layer 1118 and the light emitting element ED.

Further, the first connection electrode CE1 and the second connection electrode CE2 can be disposed on the third planarization layer 1119. The first connection electrode CE1 and the second connection electrode CE2 can be disposed above the plurality of light emitting elements ED. Each of the first connection electrode CE1 and the second connection electrode CE2 can be connected to the first electrode 124 and the second electrode 125 of each of the plurality of light emitting elements ED through a contact hole formed in the third planarization layer 1119.

The first connection electrode CE1 can be an electrode for electrically connecting the light emitting element ED and the power line VDD. The first connection electrode CE1 can be connected to the first reflection electrode RE1 through the contact hole formed in the third planarization layer 1119, the second planarization layer 1118, and the adhesive layer AD. Accordingly, the first connection electrode CE1 can be electrically connected to the power line VDD through the first reflection electrode RE1.

Further, the first connection electrode CE1 can be connected to the plurality of first electrodes 124 of each of the plurality of light emitting elements ED. At this time, the first connection electrode CE1 can be in contact with the plurality of first electrodes 124 of the light emitting element ED. For example, the first connection electrode CE1 can be disposed above the light emitting element ED to be connected to the plurality of first electrodes 124 of each of the plurality of light emitting elements ED through the contact hole formed in the third planarization layer 1119. In the meantime, the first connection electrode CE1 can be connected only to one first electrode 124, among the plurality of first electrodes 124 of the light emitting element ED, but is not limited thereto.

At this time, the first connection electrode CE1 can be in contact with the plurality of first electrodes 124 of the light emitting element ED. For example, the first connection electrode CE1 can be disposed above the light emitting element ED to be connected to the plurality of first electrodes 124 of each of the plurality of light emitting elements ED through the contact hole formed in the third planarization layer 1119. In the meantime, the first connection electrode CE1 can be connected to the plurality of first electrodes 124 of the light emitting element ED, but is not limited thereto.

The second connection electrode CE2 can be connected to the second reflection electrode RE2 through the contact hole formed in the third planarization layer 1119, the second planarization layer 1118, and the adhesive layer AD. Accordingly, the second connection electrode CE2 can be electrically connected to any one of the source electrode SE and the drain electrode DE of the driving transistor DT through the second reflection electrode RE2.

Further, the second connection electrode CE2 can be disposed on the same plane as the first connection electrode CE1. The second connection electrode CE2 can be disposed above the light emitting element ED to be connected to the second electrode 125 of each of the plurality of light emitting elements ED through the contact hole formed in the third planarization layer 1119. Accordingly, the second connection electrode CE2 can electrically connect the driving transistor DT to the second electrode 125 of the plurality of light emitting elements ED.

The protection layer 170 can be disposed on the second connection electrode CE2.

A black matrix can be further disposed on the third planarization layer 1119 to reduce the color mixture between the plurality of sub pixels SP.

Accordingly, in the light emitting element ED according to another example embodiment of the present disclosure and the display device 1100 including the same, the plurality of first electrodes 124 and the second electrode 125 are disposed on all the surfaces of the light emitting element ED. For example, the second electrode 125 can be disposed in an area corresponding to the center portion, on each of the top surface, the side surface, and the bottom surface of the light emitting element ED and the plurality of first electrodes 124 can be disposed in an area corresponding to the vertex. Therefore, the light emitting element ED can be connected to the display panel PN regardless of the position of the light emitting element ED so that the problems of the contact failure or the driving failure of the display panel PN and the light emitting element ED can be suppressed.

Further, in the light emitting element ED according to another example embodiment of the present disclosure and the display device 1100 including the same, during both a primary transferring process of transferring the plurality of light emitting elements ED to the donor and a secondary transferring process of transferring the plurality of light emitting elements attached to the donor to the display panel PN, even though the light emitting element ED is laid down or flipped over, the plurality of light emitting elements ED and the display panel PN can be connected. Further, during the process of transferring the plurality of light emitting elements ED assembled on the assembling substrate to the display panel PN, even though the light emitting element ED is laid down or flipped over, the problems of the contact failure or the driving failure of the display panel PN and the light emitting element ED can be suppressed.

Further, in the light emitting element ED according to another example embodiment of the present disclosure and the display device 1100 including the same, the first connection electrode CE1 and the second connection electrode CE2 which connect the light emitting element ED and the driving transistor DT and the power line VDD are disposed above the light emitting element ED. Therefore, the first connection electrode CE1 and the second connection electrode CE2 can be electrically connected to the plurality of first electrodes 124 and the second electrode 125 disposed above the light emitting element ED. Accordingly, in the light emitting element ED according to another example embodiment of the present disclosure and the display device 1100 including the same, the light emitting element ED can be connected with a lateral structure.

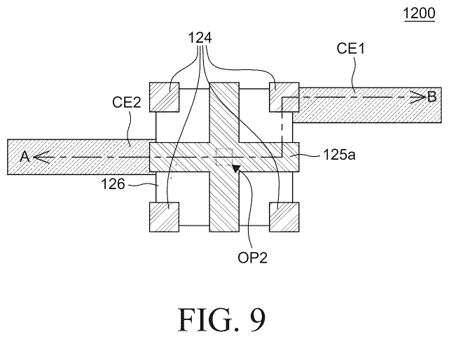

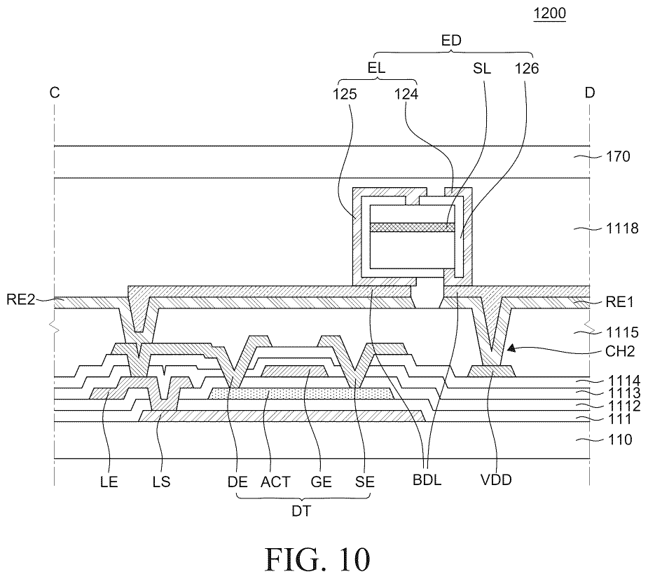

FIG. 9 is a plan view of a sub pixel of a display device according to still another example embodiment of the present disclosure. FIG. 10 is a cross-sectional view taken along the line C-D of FIG. 9. In FIG. 9, for the convenience of illustration, the light emitting element ED, the first connection electrode CE1, and the second connection electrode CE2 are illustrated. Only a first connection electrode CE1 and a second connection electrode CE2 of a display device 1200 of FIGS. 9 and 10 are different from those of the display device 1100 of FIGS. 7 and 8 and the adhesive layer AD and the third planarization layer 1119 are not disposed in the display device 1200 of FIGS. 9 and 10. However, the other configuration is the substantially same so that a redundant description will be omitted.

Referring to FIG. 10, the first connection electrode CE1 and the second connection electrode CE2 can be disposed on the first planarization layer 1115 and the first reflection electrode RE1 and the second reflection electrode RE2. The first connection electrode CE1 and the second connection electrode CE2 can be disposed below the light emitting elements ED. Specifically, the first connection electrode CE1 can be in contact with the plurality of first electrodes 124 disposed below the light emitting element ED and the second connection electrode CE2 can be in contact with the second electrode 125 disposed below the light emitting element ED.

The first connection electrode CE1 and the second connection electrode CE2 can fix the plurality of light emitting elements ED on the first reflection electrode RE1 and the second reflection electrode RE2.

In the meantime, the first connection electrode CE1 and the second connection electrode CE2 can be formed of Eutectic metal. For example, the first connection electrode CE1 and the second connection electrode CE2 are formed of tin (Sn)—gold (Au) alloy, indium (In), zinc (Zn), lead (Pb), nickel (Ni), gold (Au), platinum (Pt), copper (Cu), or an alloy thereof, but are not limited thereto.

In the meantime, the first connection electrode CE1 can be connected only to one first electrode 124, among the plurality of first electrodes 124 of the light emitting element ED, but is not limited thereto.

Referring to FIG. 10, the light emitting element ED and the second planarization layer 1118 which encloses the light emitting element ED can be disposed on the first connection electrode CE1 and the second connection electrode CE2 and the protection layer 170 can be disposed above the second planarization layer 1118.

In the light emitting element ED according to still another example embodiment of the present disclosure and the display device 1200 including the same, the plurality of first electrodes 124 and the second electrode 125 can be disposed on all the surfaces of the light emitting element ED. Therefore, the light emitting element ED can be connected to the display panel PN regardless of the position of the light emitting element ED so that the problems of the contact failure or the driving failure of the display panel PN and the light emitting element ED can be suppressed.

Further, in the light emitting element ED according to still another example embodiment of the present disclosure and the display device 1200 including the same, even though the light emitting element ED is laid down or flipped over during the process of transferring the plurality of light emitting elements ED to the display panel PN, the problem of the contact failure or the driving failure of the display panel PN and the light emitting element ED can be suppressed.

Further, in the light emitting element ED according to another example embodiment of the present disclosure and the display device 1200 including the same, the first connection electrode CE1 and the second connection electrode CE2 which connect the light emitting element ED and the driving transistor DT and the power line VDD are disposed below the light emitting element ED. Therefore, the first connection electrode CE1 and the second connection electrode CE2 can be electrically connected to the plurality of first electrodes 124 and the second electrode 125 disposed below the light emitting element ED. Accordingly, in the light emitting element ED according to the example embodiment of the present disclosure and the display device 1200 including the same, the light emitting element ED can be connected in a flip-chip structure.

The example embodiments of the present disclosure can also be described as follows:

According to an aspect of the present disclosure, there is provided a light emitting element. The light emitting element comprises a semiconductor layer; and a plurality of electrodes which is in contact with a part of the semiconductor layer, wherein the semiconductor layer includes a first semiconductor layer; an emission layer on the first semiconductor layer; and a second semiconductor layer on the emission layer, the plurality of electrodes includes: a plurality of first electrodes which is disposed so as to correspond to a corner of the semiconductor layer; and a second electrode which is spaced apart from the plurality of first electrodes and is disposed in a center portion of a surface of the semiconductor layer.

Each of the plurality of first electrodes can be disposed so as to cover a corner of a side surface of the semiconductor layer.

Each of the plurality of first electrodes can be disposed so as to cover a vertex of a top surface of the semiconductor layer and a vertex of a bottom surface of the semiconductor layer.

The second electrode can include a first part on a top surface of the semiconductor layer; a second part on a bottom surface of the semiconductor layer; and a third part which is disposed on a side surface of the semiconductor layer and is electrically connected to the first part and the second part, the first part and the second part have the same shape and the first part and the second part can have a different shape from the third part.

The first part and the second part can have a cross shape.

The third part can extend from a corner at which the top surface and the side surface of the semiconductor layer meet toward a corner at which the bottom surface and the side surface of the semiconductor layer meet.

The light emitting element can further comprise an encapsulation layer which covers a part of the semiconductor layer, the encapsulation layer can include at least one or more first openings which expose a part of the bottom surface of the first semiconductor layer; and at least one or more second openings which expose a part of the top surface of the second semiconductor layer, the second opening can be disposed in a center portion of the top surface of the second semiconductor layer and the first opening can be disposed so as to correspond to a corner of the bottom surface of the first semiconductor layer.

The first opening, the first electrode and the first semiconductor layer can be in contact with each other and in the second opening, the second electrode and the second semiconductor layer can be in contact with each other.

At least one of the plurality of electrodes can include a ferromagnetic material.

According to an aspect of the present disclosure, there is provided a display device. The display device comprises a substrate including a plurality of sub pixels; a plurality of transistors on the substrate; and a plurality of light emitting elements which is disposed on the plurality of sub pixels on the plurality of transistors.

The display device can further comprise a first assembly electrode and a second assembly electrode which are disposed to be spaced apart from each other below the plurality of light emitting elements, wherein a plurality of first electrodes of each of the plurality of light emitting elements can be electrically connected to the first assembly electrode and the second assembly electrode and a second electrode of each of the plurality of light emitting elements can be disposed between the first assembly electrode and the second assembly electrode.

The display device can further comprise a first connection electrode which is connected to the plurality of first electrodes; and a second connection electrode which is connected to the second electrode, wherein the first connection electrode and the second connection electrode can be disposed on different planes.

The display device can further comprise a reflection electrode below the plurality of light emitting elements; and an adhesive layer which is disposed on a bottom surface of the plurality of light emitting elements to be bonded with the plurality of light emitting elements, wherein the adhesive layer can be in contact with a part of the plurality of first electrodes and a part of the second electrode.

The display device can further comprise a first connection electrode which is connected to the plurality of first electrodes; and a second connection electrode which is connected to the second electrode, wherein the first connection electrode and the second connection electrode can be disposed on the same plane.

The first connection electrode and the second connection electrode can be connected to the plurality of light emitting elements above the plurality of light emitting elements.

The first connection electrode and the second connection electrode can be connected to the light emitting elements below the plurality of light emitting elements.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A light emitting element, comprising:
a semiconductor layer; and
a plurality of electrodes in contact with parts of the semiconductor layer,
wherein the semiconductor layer includes:
a first semiconductor layer;
an emission layer on the first semiconductor layer; and
a second semiconductor layer on the emission layer, and
wherein the plurality of electrodes includes:
a plurality of first electrodes disposed to correspond to corners of the semiconductor layer; and
a second electrode spaced apart from the plurality of first electrodes disposed in a center portion of a surface of the semiconductor layer.

2. The light emitting element according to claim 1, wherein the semiconductor layer includes a first surface, a second surface and a third second surface,
wherein one first electrode of the plurality of first electrodes covers a corner of the covers of the third surface of the semiconductor layer.

3. The light emitting element according to claim 2, wherein the one first electrode covers a vertex of the second surface of the semiconductor layer and a vertex of the first surface of the semiconductor layer.

4. The light emitting element according to claim 1, wherein the semiconductor layer includes a first surface, a second surface and a third second surface,
wherein the second electrode includes:
a first part on the second surface of the semiconductor layer;
a second part on the first surface of the semiconductor layer; and
a third part on the third surface of the semiconductor layer and electrically connected to the first part and the second part, and
wherein the first part and the second part have a same shape, and the first part and the second part have a different shape from the third part.

5. The light emitting element according to claim 4, wherein the first part and the second part have a cross shape.

6. The light emitting element according to claim 4, wherein the third part extends from a corner of the corners at which the second surface and the third surface of the semiconductor layer meet toward a corner of the corners at which the first surface and the third surface of the semiconductor layer meet.

7. The light emitting element according to claim 1, further comprising:
an encapsulation layer to cover a part of the semiconductor layer,
wherein the encapsulation layer includes:
at least one first opening to expose a part of a first surface of the first semiconductor layer; and
at least one second opening to expose a part of a second surface of the second semiconductor layer, and
wherein the at least one second opening is disposed in a center portion of the second surface of the second semiconductor layer and the at least one first opening is disposed to correspond to a corner of the second surface of the first semiconductor layer.

8. The light emitting element according to claim 7, wherein in the at least one first opening, the first electrode and the first semiconductor layer are contact with each other and in the at least one second opening, the second electrode and the second semiconductor layer are contact with each other.

9. The light emitting element according to claim 8, wherein at least one of the plurality of electrodes includes a ferromagnetic material.

10. The light emitting element according to claim 1, wherein the semiconductor layer is cubical.

11. The light emitting element according to claim 4, wherein, at each of the first surface, the second surface and the third surface, the second electrode is interposed between adjacent first electrodes of the plurality of first electrodes.

12. A display device, comprising:
a substrate including a plurality of sub pixels;
a plurality of transistors on the substrate; and
a plurality of light emitting elements, each light emitting element being the light emitting element according to claim 1,
wherein the plurality of light emitting elements are disposed on the plurality of sub pixels on the plurality of transistors.

13. The display device according to claim 12, further comprising:
a first assembly electrode and a second assembly electrode disposed to be spaced apart from each other below the plurality of light emitting elements,
wherein the plurality of first electrodes of each of the plurality of light emitting elements is electrically connected to the first assembly electrode and the second assembly electrode, and the second electrode of each of the plurality of light emitting elements is disposed between the first assembly electrode and the second assembly electrode.

14. The display device according to claim 12, further comprising:
a first connection electrode connected to the plurality of first electrodes; and
a second connection electrode connected to the second electrode,
wherein the first connection electrode and the second connection electrode are disposed on different planes.

15. The display device according to claim 12, further comprising:
a reflection electrode below the plurality of light emitting elements; and
an adhesive layer disposed on a first surface of the plurality of light emitting elements to be bonded with the plurality of light emitting elements,
wherein the adhesive layer is in contact with a part of the plurality of first electrodes and a part of the second electrode.

16. The display device according to claim 12, further comprising:
a first connection electrode connected to the plurality of first electrodes; and
a second connection electrode connected to the second electrode,
wherein the first connection electrode and the second connection electrode are disposed on the same plane.

17. The display device according to claim 16, wherein the first connection electrode and the second connection electrode are connected to first surfaces of the plurality of light emitting elements.

18. The display device according to claim 16, wherein the first connection electrode and the second connection electrode are connected to second surfaces of the plurality of light emitting elements.

19. A light emitting element comprising:
a semiconductor structure; and
a plurality of electrodes on a plurality of surfaces of the semiconductor structure,
wherein the plurality of electrodes include:
a plurality of first electrodes on each of the plurality of surfaces of the semiconductor structure; and
a second electrode on each of the plurality of surfaces of the semiconductor structure, and spaced apart from the plurality of first electrodes at each of the plurality of surfaces of the semiconductor structure.

20. The light emitting element according to claim 19, wherein the semiconductor structure is cubical.

21. The light emitting element according to claim 19, wherein the plurality of surfaces include 6 surfaces.
